(19) United States
(12) Patent Application Publication
(10) Pub. No.: US 2026/0305320 A1
(43) Pub. Date: Oct. 1, 2026

(54) EMBEDDED FERROELECTRIC CAPACITORS IN THE BACK END OF LINE FOR FERROELECTRIC RANDOM ACCESS MEMORY

(71) Applicant: Intel Corporation, Santa Clara, CA (US)

(72) Inventors: Nazila Haratipour, Portland, OR (US); Christopher M. Neumann, Portland, OR (US); Allen B. Gardiner, Portland, OR (US); Muhammad Nisar, Hillsboro, OR (US); Shriram Shivaraman, Hillsboro, OR (US); Yu-Ching Liao, Portland, OR (US); Sou-Chi Chang, Portland, OR (US); Nancy Zelick, Portland, OR (US); Chia-Ching Lin, Portland, OR (US); Bharath Bangalore Rajeeva, Smyrna, GA (US); Uygar E. Avci, Portland, OR (US)

(73) Assignee: Intel Corporation, Santa Clara, CA (US)

(21) Appl. No.: 19/094,525

(22) Filed: Mar. 28, 2025

(51) Int. Cl. H01L 23/522; H01L 23/528; H10B 53/20; H10B 53/30; H10D 1/68

(52) U.S. Cl. CPC H10W 20/496; H10B 53/20; H10B 53/30; H10D 1/682; H10D 1/716; H10W 20/42; H10W 20/435

(57) ABSTRACT

Ferroelectric capacitors may be embedded in a stack structure of an integrated circuit device as part of on-chip ferroelectric random access memory (FeRAM). An example integrated circuit device comprises a device layer and a stack structure above the device layer. The device layer includes a first transistor. The stack structure includes a first layer with a first interconnect structure and a dielectric material, and a second layer between the device layer and the first layer. The integrated circuit device further includes a capacitor in a cavity within the stack structure. The capacitor includes a first conductive portion, a second conductive portion conductively coupled to the first transistor, and a dielectric portion comprising ferroelectric material. The dielectric portion is located between the first conductive portion of the capacitor and the second conductive portion of the capacitor.

### BACKGROUND

Advances in processor performance has resulted in a performance gap with other components such as main memory or dynamic random access memory (DRAM). This performance gap continues to increase as the performance improvements of processors are realized at a faster rate than the performance improvements of memory. Additionally, as the size of integrated circuits continues to shrink, designing memory structures for storing and retrieving information used by a central processing unit (CPU) presents challenges.

### BRIEF DESCRIPTION OF THE DRAWINGS

FIG. 1 is a simplified cross-sectional view of example processing layers of a wafer or a die showing example alternative locations of ferroelectric capacitors of a ferroelectric random access memory (FeRAM) array in an integrated circuit component.

FIG. 2A is a simplified cross-sectional view of a first side of an integrated circuit structure showing two example embedded ferroelectric capacitors of an FeRAM array.

FIG. 2B is another simplified cross-sectional view of a second side of the integrated circuit structure of FIG. 2A.

FIG. 3 is an example method of a manufacturing flow for an integrated circuit component with ferroelectric capacitors embedded in the back end of line.

FIG. 4 is a top view of a wafer and dies that may be included in a microelectronic assembly, in accordance with any of the embodiments disclosed herein.

FIG. 5 is a cross-sectional view of an integrated circuit structure that may be included in any of the microelectronic assemblies disclosed herein.

FIGS. 6A-6D are perspective views of example planar, FinFET, gate-all-around, and stacked gate-all-around transistors.

FIG. 7 is a cross-sectional view of an integrated circuit device assembly that may include a microelectronic assembly, in accordance with any of the embodiments disclosed herein.

FIG. 8 is a block diagram of an example electrical device that may include a microelectronic assembly, in accordance with any of the embodiments disclosed herein.

### DETAILED DESCRIPTION

The present disclosure provides various possible embodiments, or examples, of architectures, assemblies, apparatuses, systems, and methods associated with ferroelectric random access memory (FeRAM) cells embedded in an integrated circuit structure in the back end of line (BEOL) processing.

For purposes of understanding the embodiments in this disclosure, the following contextual information related to the challenges of designing integrated circuits with memory structures is provided. Generally, the performance of processors has grown at a much faster rate than the performance of memory devices. If the memory performance does not keep pace with processor speed in operation, bottlenecks can prevent the full potential of processor from being realized. Minimizing the distance between memory and a processor (e.g., a CPU) can reduce the communication distance between the memory and the CPU and facilitate faster data access. Forming memory structures directly on an integrated circuit die, however, presents numerous challenges due to area constraints, scalability, and fabrication complexity.

Dynamic random access memory (DRAM) is volatile memory that can be embedded in the back end of line (BEOL) of an integrated circuit. DRAM includes 1 transistor and 1 capacitor (1T-1C) to store one bit by putting a charge on the capacitor. Embedded DRAM in the back end of line of an integrated circuit can reduce the communication distance between a central processing unit (CPU) and the embedded memory and provide faster data access. With DRAM, however, the charge leaks off the capacitor through the transistor over time. The leakage effectively limits retention and affects the design of the memory cell. In particular, the DRAM must be continuously refreshed in order to hold the stored data. In addition, scalability can be hindered by the leakage because high aspect ratio (AR) capacitors are needed to maintain high capacitance and minimize the die area consumed by the memory. The term “high AR” refers to a high height-to-width ratio for the capacitors, which is achieved by deep trench or stacked capacitors.

Static random access memory (SRAM) is a type of RAM that uses latching circuitry to store each bit. SRAM is considered volatile memory but retains data without requiring a refresh circuit. SRAM is often used for cache, where it is integrated in the same chip as a processor. SRAM requires 6 transistors per bit, however, making it inefficient for scaling. As semiconductor technology advances continue to decrease the size of integrated circuits, more SRAM memory cells per unit can be realized. Reliance on the reduction of physical size of SRAM (referred to as “SRAM area scaling”), however, has slowed significantly. Thus, improvements in memory capacity using SRAM has been unable to keep up with improvements in processor performance.

Embodiments disclosed herein can resolve the aforementioned issues (and more) associated with enhancing the performance of memory used by processors. In this example, one or more ferroelectric capacitors are implemented between any metal stack (e.g., interconnect layers of interspersed metal and dielectric materials) in a back end of line (BEOL) stack structure of an integrated circuit component. In some examples, ferroelectric capacitors are used as storage elements of a non-volatile memory application (e.g., FeRAM). Thus, the integration of ferroelectric capacitors using the existing interconnect layers for connections can achieve embedded dense memory on chip. Existing interconnect layers can provide connections from an array of ferroelectric capacitors embedded in interconnect layers to transistors in a device layer and to a plate line for receiving read/write signals across the array of embedded ferroelectric capacitors. Thus, high-density, high-speed memory is enabled for integrated circuits in which the ferroelectric capacitors are embedded in the interconnect layers of the BEOL stack structure.

Several advantages are realized by embedding an array of ferroelectric capacitors in the interconnect layers of a stack structure during back end of line (BEOL) processing. For example, ferroelectric capacitors that are embedded in the interconnect layers of an integrated circuit component as part of an FeRAM array provide for short communication paths that facilitate faster data access, faster data transfer, and faster calculations in the logic, without requiring the use of low-leakage transistors, which is typically used with DRAM. FeRAM involves the use of a ferroelectric material in a capacitor as opposed to a typical dielectric material. The ferroelectric material (e.g., a layer of Fe material) is positioned between two electrodes (e.g., two conductive portions). When a field is applied across the electrodes, a different voltage is present on the outer electrode and the inner electrode. Once the atoms in the Fe layer polarize, the polarization persists even when the field goes away. Unlike DRAM, a charge is not stored on the metal electrodes of a ferroelectric capacitor and thus, the leakage issue is avoided. In addition, the bit is stored in the Fe layer of a ferroelectric capacitor, which effectively renders the FeRAM non-volatile memory since decay is minimal. Also, since a continuous refresh rate is not required with FeRAM, power consumption is lower as compared to DRAM, for example. Moreover, ferroelectric capacitors can be embedded in BEOL processing and is a back-end compatible process. High AR capacitors are not required due to the high charge density of FeRAM. Moreover, FeRAM can enable three dimensional (3-D) scaling and stacking on capacitors, which may be similar to 3D NAND (NOT AND) architecture.

Reference is now made to the drawings, which are not necessarily drawn to scale, wherein similar or same numbers may be used to designate same or similar parts in different figures. The use of similar or same numbers in different figures does not mean all figures including similar or same numbers constitute a single or same embodiment. Like numerals having different letter suffixes may represent different instances of similar components. The drawings illustrate generally, by way of example, but not by way of limitation, various embodiments discussed in the present document.

In the following description, for purposes of explanation, numerous specific details are set forth in order to provide a thorough understanding thereof. It may be evident, however, that the novel embodiments can be practiced without these specific details. In other instances, well-known structures and devices are shown in block diagram form in order to facilitate a description thereof. The intention is to cover all modifications, equivalents, and alternatives within the scope of the claims.

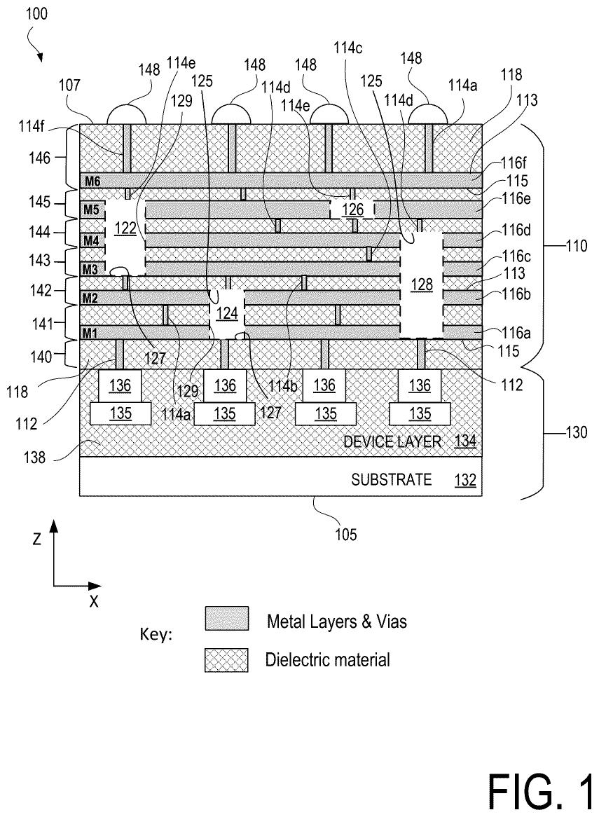

FIG. 1 is a simplified cross-sectional view of an example processing layers 100 of a wafer or die showing example alternative positions of ferroelectric capacitors embedded in the processing layers of the wafer or die. Ferroelectric capacitors may be used in ferroelectric random access memory (FeRAM) cells implemented in the integrated circuit of the die. The cross-sectional view of the processing layers 100 shows a BEOL stack structure 110 comprising interconnect layers of an inter-layer dielectric (ILD) stack (or metallization stack) that may be located toward the top or upper surface 107 of the wafer or die. The cross-sectional view also shows a front end of line (FEOL) structure 130 (e.g., a device layer, a substrate) that may be located toward the bottom or lower surface 105 of the wafer or die. Generally, a FEOL fabrication process involves device formation (e.g., transistors, resistors, capacitors, inductors, etc. in a device layer), and a BEOL fabrication process involves the fabrication of interconnects or wiring (e.g., traces and vias in interconnect layers) of the integrated circuit.

As used herein, the “frontside” of a wafer, die, or substrate may include the BEOL stack structure 110 and an active region such as device layer 134 where processing is performed. The “backside” of a wafer, or die, or substrate may include the substrate or a portion thereof including the lower surface 105. In some implementations, the backside may also include backside processing layers.

In a generalized example associated with the processing layers 100 shown in FIG. 1, a semiconductor wafer or die may include a substrate 132 or a semiconductor substrate, a device layer 134, a plurality of interconnect layers 140-146, and conductive contacts 148. An integrated circuit structure may be formed on a substrate 132 or semiconductor substrate. The substrate 132 may be any semiconductor substrate composed of semiconductor material including, for example, n-type materials, p-type materials, or a suitable combination thereof.

The device layer 134 includes semiconductor devices, such as transistors 135 (e.g., MOSFETs) for processing electrical signals. At least some transistors act as switches forming the basis of logic gates in which binary 1s and 0s represent data. The device layer 134 may also include other semiconductor devices including, for example, capacitors, resistors, diodes, and/or inductors. The device layer 134 may include a dielectric material 138 within which the transistors 135 are disposed and upon which a bottom layer of the BEOL stack structure 110 is located. Conductive contacts 136 (also referred to as a “contact layer”) may be provided in the device layer 134 to provide electrical connections to interconnect structures and devices (e.g., ferroelectric capacitors) in the BEOL stack structure 110, and/or conductive contacts 148 on the BEOL stack structure 110. In the device layer 134, conductive contacts 136 may provide electrical connections between lowest metal vias 112 (also referred to as “V0”) of the BEOL stack structure 110 and source and/or drain regions of the transistors 135. It should be noted that, in at least some scenarios, one or more portions of a transistor (or other device in the device layer) may extend into the lowest interconnect layer (e.g., first interconnect layer 140) in which the lowest metal vias 112 are located.

The BEOL stack structure 110 may be formed as interconnect layers 140-146 comprising insulating material or dielectric material 118 and/or oxides, interspersed with interconnect structures such as vias 112 and 114a-114f and lines 116a-116f (or traces) comprising electrically conductive material, such as metal. The lines define various metal layers (e.g., M1, M2, M3, M4, M5, and M6) and the vias define through dielectric vias (TDVs). The dielectric material 118 in different ones of the interconnect layers 140-146 may have the same composition or different compositions. In various embodiments, the upper metal layers M1-M6 may have the same thickness (or height) or different thicknesses (or heights). In one example, a metal layer in which the capacitor is embedded may have a larger Z-axis dimension than the other metal layers. For example, if a ferroelectric capacitor is embedded in a single metal layer (e.g., the fifth metal layer M5 at cavity 126), then the Z-axis dimension of M5 may be increased to allow for a taller capacitor without encroaching on the other metal layers. In yet other scenarios, multiple metal layers may have a larger Z-dimension to accommodate an embedded ferroelectric capacitor in those multiple layers. In further examples, the one or more metal layers in which the ferroelectric capacitor is embedded may have the same Z-dimension as other metal layers. In another example, the upper metal layers (e.g., M5, M6) are thinner in the Z-axis direction than the lower metal layers (e.g., M1, M2, M3, M4). As used herein, a thin layer of metal can be less than 20 nanometers +/−5% in the Z-axis direction.

Each metal layer M1-M6 in an interconnect layer (e.g., interconnect layers 141-146) is defined between a respective pair of planes (e.g., an upper plane 113 and a lower plane 115), which are substantially parallel and spaced apart in the Z-axis direction. The upper plane 113 is defined by upper edges of the lines formed in the interconnect layer and the lower plane 115 is defined by lower edges of the lines formed in the interconnect layer. In various aspects of the disclosure, the interconnect structures are to provide at least one electrical path from a node in the device layer 134 through the interconnect layers 140-146 to a conductive contact on the upper surface 107 or to an array of ferroelectric capacitors embedded in the interconnect layers (e.g., ferroelectric capacitors disposed in cavities 122, 124, 126, 128 within the interconnect layers 140-146). The conductive contacts may be electrically coupled to the integrated circuitry of a chiplet region or active region in another die, e.g., via a through silicon via (TSV) or a TDV.

For simplicity, lines 116a-116f are illustrated as solid metal layers spanning the width of the processing layers 100 shown in FIG. 1. In addition, an example number and placement of vias 114a-114f and 112 are illustrated in the processing layers 100. It should be noted, however, that based on the particular needs and/or requirements of an integrated circuit component, lines (e.g., 116a-116f) and vias (e.g., 114a-114g and 112) of the interconnect layers (e.g., 140-146) may be formed in any suitable pattern that creates electrically conductive paths to route electrical signals to and/or from devices (e.g., transistors 135) in a device layer (e.g., 134), to and/or from conductive contacts (e.g., 148), and to and/or from embedded semiconductor devices (e.g., ferroelectric capacitors disposed in cavities 122, 124, 126, or 128). For example, one or more of the solid metal layers M1-M6 shown in FIG. 1 may be formed into multiple metal lines within the same layer, where the multiple metal lines of a layer are separated by an insulating or dielectric material 118.

Although the lines 116a-116f and vias 112 and 114a-114f are structurally delineated with a line within individual interconnect layers for the sake of clarity, the lines 116a-116f and vias 112 and 114a-114f may be structurally and/or materially contiguous (e.g., simultaneously filled during a dual-damascene process) in some embodiments. Furthermore, fewer interconnect layers or more interconnect layers may be provided in the BEOL stack structure 110 based on the particular needs and/or requirements of the integrated circuit component.

In FIG. 1, the vias 112 and 114a-114f are each disposed in a single one of the interconnect layers 140-146. It should be noted, however, that any one or more of the vias 112 and 114a-114f may, alternatively, extend through (or traverse) multiple interconnect layers. For example, a via may extend through multiple interconnect layers to connect a line in a first interconnect layer to a line in a second interconnect layer, where the first interconnect layer is not adjacent to the second interconnect layer such that one or more other interconnect layers are disposed between the first and second interconnect layers. In another example, a via may extend through (or traverse) multiple interconnect layers to connect a conductive contact (e.g., conductive contact on the BEOL stack structure, in the device layer, or on the substrate) to a line in a first interconnect layer, where one or more other interconnect layers are disposed between the conductive contact and the first interconnect layer. In another example, a via may extend through (or traverse) multiple interconnect layers to connect a first conductive contact (e.g., conductive contact on the BEOL stack structure) to a second conductive contact (e.g., conductive contact in the device layer or on the substrate), where one or more interconnect layers are disposed between the first and second conductive contacts.

In FIG. 1, vias to be connected to embedded ferroelectric capacitors in the cavities 122, 124, 126, and 128, are located in a single interconnect layer (e.g., 140-146), it should be noted that any one or more of the vias connected to an embedded ferroelectric capacitor may extend through (or traverse) multiple interconnect layers.

An example configuration of the interconnect structures in the interconnect layers 140-146 will now be described. For simplicity, each of the vias 112 and 114a-114f in FIG. 1 are shown and described below as being disposed in a single interconnect layer.

A first interconnect layer 140 includes the lowest metal vias (which can be referred to as a Via 0 or “V0”) of the BEOL stack structure 110 and may be formed directly on the device layer 134. In some embodiments, the first interconnect layer 140 may include V0 vias 112 to electrically couple one or more conductive contacts 136 of transistors 135 in the device layer 134 to one or more lines 116a of the second interconnect layer 141. In this case, lower ends of the one or more vias 112 are electrically coupled to the one or more conductive contacts 136, respectively, and upper ends of the one or more vias 112 are electrically coupled to the one or more lines 116a, respectively, of the second interconnect layer 141.

The second interconnect layer 141 may be formed directly on the first interconnect layer 140. In some embodiments, the second interconnect layer 141 may include vias 114a to electrically couple one or more lines 116a of the second interconnect layer 141 with one or more lines 116b, respectively, of a third interconnect layer 142. In this case, lower ends of the one or more vias 114a are electrically coupled to the one or more lines 116a in the second interconnect layer 141, and upper ends of the one or more vias 114a are electrically coupled to the one or more lines 116b in the third interconnect layer 142. The lines 116a may also be referred to as Metal 1 or “M1” layer. The vias 114a may also be referred to as Via 1 or “V1.”

The third interconnect layer 142 may be formed directly on the second interconnect layer 141. In some embodiments, the third interconnect layer 142 may include vias 114b to electrically couple one or more lines 116b of the third interconnect layer 142 with one or more lines 116c, respectively, of a fourth interconnect layer 143. In this case, lower ends of the one or more vias 114b are electrically coupled to the one or more lines 116b in the third interconnect layer 142, and upper ends of the one or more vias 114b are electrically coupled to the one or more lines 116c in the fourth interconnect layer 143. The lines 116b may also be referred to as Metal 2 or “M2” layer. The vias 114b may also be referred to as Via 2 or “V2”.

The fourth interconnect layer 143 may be formed directly on the third interconnect layer 142. In some embodiments, the fourth interconnect layer 143 may include vias 114c to electrically couple one or more lines 116c of the fourth interconnect layer 143 with one or more lines 116d, respectively, of a fifth interconnect layer 144. In this case, lower ends of the one or more vias 114c are electrically coupled to the one or more lines 116c in the fourth interconnect layer 143, and upper ends of the one or more vias 114c are electrically coupled to the one or more lines 116d in the fifth interconnect layer 144. The lines 116c may also be referred to as Metal 3 or “M3” layer. The vias 114c may also be referred to as Via 3 or “V3.”

The fifth interconnect layer 144 may be formed directly on the fourth interconnect layer 143. In some embodiments, the fifth interconnect layer 144 may include vias 114d to electrically couple one or more lines 116d of the fifth interconnect layer 144 with one or more lines 116e, respectively, of a sixth interconnect layer 145. In this case, lower ends of the one or more vias 114d are electrically coupled to the one or more lines 116d in the fifth interconnect layer 144, and upper ends of the one or more vias 114d are electrically coupled to the one or more lines 116e in the sixth interconnect layer 145. The lines 116d may also be referred to as Metal 4 or “M4” layer. The vias 114d may also be referred to as Via 4 or “V4.”

The sixth interconnect layer 145 may be formed directly on the fifth interconnect layer 144. In some embodiments, the sixth interconnect layer 145 may include vias 114e to electrically couple one or more lines 116e of the fifth interconnect layer 145 with one or more lines 116f, respectively, of a seventh interconnect layer 146. In this case, lower ends of the one or more vias 114e are electrically coupled to the one or more lines 116e in the sixth interconnect layer 145, and upper ends of the one or more vias 114e are electrically coupled to the one or more lines 116f in the seventh interconnect layer 146. The lines 116e may also be referred to as Metal 5 or “M5” layer. The vias 114e may also be referred to as Via 5 or “V5.”

The seventh interconnect layer 146 may be formed directly on the sixth interconnect layer 145. In some embodiments, the seventh interconnect layer 146 may include vias 114f to electrically couple one or more lines 116f of the seventh interconnect layer 146 with one or more conductive contacts 148, respectively. In this case, lower ends of the one or more vias 114f are electrically coupled to the one or more lines 116f in the seventh interconnect layer 146, and upper ends of the one or more vias 114f are electrically coupled to the one or more conductive contacts 148 on the BEOL stack structure 110. The lines 116f may also be referred to as Metal 6 or “M6” layer. The vias 114f may also be referred to as Via 6 or “V6.”

Conductive contacts 148 may be formed on the upper surface 107 of the BEOL stack structure 110. It should be noted that, instead of being electrically coupled to a lower edge of a line in a higher metal layer, any of the vias (e.g., 112, 114a-114e) could be electrically coupled directly to a conductive contact 148. In some examples, conductive contacts may also be formed on a lower surface 105 of the substrate or backside. The conductive interconnects and contacts generally comprise a metal, such as copper (Cu). In some embodiments, the conductive interconnects and contacts may include one or more of gold, tungsten, aluminum, titanium, tantalum, molybdenum, magnesium, and cobalt (W, Mo, Ti, Au, Mg, Ta, Co, Al).

Other integrated circuit components (also referred to herein as “integrated circuits”) may be electrically coupled to the device layer 134, for example, through the conductive contacts 148 (e.g., solder bumps) on the upper surface 107 of the BEOL stack structure and through the interconnect layers 140-146. In one example, the conductive contacts 148 may be connected to conductive lines on a printed circuit board. The lower surface 105 may include conductive contacts (e.g., solder bumps) to attach to a solder silicon interposer or to an organic package.

In one or more embodiments, ferroelectric capacitors may be monolithically integrated in one or more interconnect layers (e.g., interconnect layers 140-146) on top of logic (e.g., in device layer 134) in an integrated circuit structure, which may be included in an integrated circuit component. The cross-sectional view of the BEOL stack structure 110 in FIG. 1 illustrates possible alternative positions of openings, spaces, or cavities 122, 124, 126, and 128 within the interconnect layers 140-146, in which a ferroelectric capacitor, which may be part of an FeRAM cell, can be disposed.

Each example cavity 122, 124, 126, and 128 may represent an array of adjacent cavities extending in a Y-axis direction (substantially perpendicular to both the X-axis direction and the Z-axis direction), to form a one-dimensional FeRAM array formation. It should be noted that the array of cavities to hold ferroelectric capacitors could extend in both the X-axis direction and the Y-axis direction to form a two-dimensional FeRAM array formation. Each cavity of an array of cavities holds a single ferroelectric capacitor, as each ferroelectric capacitor can store a single bit. The cavities in an array of cavities may be formed in an insulating or dielectric material (e.g., dielectric material 118). As used herein, the term “cavity” is intended to include a fully occupied (or fully-filled) structure. Thus, the ferroelectric capacitors disposed in an array of cavities in the interconnect layers may completely occupy (or fill) the cavities and may be separated from each other by the insulating or dielectric material. For example, a ferroelectric capacitor may abut dielectric sidewalls, dielectric bottom walls, and any dielectric top walls of the cavities, such that no space is defined therebetween. Vias coupling the ferroelectric capacitors to a plate line may extend through the top walls of the cavities to the ferroelectric capacitors.

Generally, a cavity within one or more interconnect layers 140-146 may have a trench-shape or any other suitable shape (e.g., oval, cylinder, open U-shape, rectangle, square, etc.) such that the cavity can hold a single ferroelectric capacitor. The cavity may include a top portion that is aligned with an upper edge of a metal layer within an interconnect layer and substantially parallel to the interconnect layers. Each cavity 122, 124, 126, and 128 shown in the interconnect layers 140-146 includes one or more sidewalls 129 connected to a bottom side 127, and an open top edge 125. Depending on the shape of the cavity, the cavity could be formed with one, two, three or more sidewalls 129. The trench shape of the cavities 122, 124, and 128 may be characterized as having a depth (e.g., sidewall 129 dimension measured along a Z-axis as shown in FIG. 1) that is longer than its width (e.g., bottom side 127 and/or top edge 125 measured along the X-axis as shown in FIG. 1) and longer than its length (e.g., measured along a Y-axis that is perpendicular to the Z-axis and X-axis). For example, the depth of a cavity may have a range of 100-500 nanometers (nm), while the width and length of the cavity may be less than the depth and have a range of 40-200 nm. In another possible example, trench shape of the cavity 126 may be characterized as having a depth (e.g., sidewall 129 dimension measured along the Z-axis) that is shorter than its width (e.g., bottom side 127 and/or top edge 125 measured along the X-axis) and length (e.g., measured along the Y-axis that is perpendicular to the Z-axis and X-axis).

An array of cavities for holding ferroelectric capacitors within the interconnect layers (e.g., interconnect layers 140-146) of an integrated circuit structure may be positioned across any number of adjacent interconnect layers, or in a single interconnect layer. The positioning of the cavities may be based on, for example, the size and/or specifications of the particular ferroelectric capacitors being used and on the particular design and specification of the integrated circuit component.

In a first example, a bottom side 127 of cavity 122 is aligned with the lower plane 115 (e.g., defined by lower edges of lines 116c) of the third metal layer M3 in the fourth interconnect layer 143, and extends to a top edge 125 aligned with the upper plane 113 (e.g., defined by the upper edges of lines 116e) of the fifth metal layer M5 in the sixth interconnect layer 145. Thus, cavity 122 traverses interconnect layers 143 and 144 and the fifth metal layer M5 (lines 116e) in the sixth interconnect layer 145. A via 114e in the sixth interconnect layer 145 is to be electrically coupled to a first electrode of a ferroelectric capacitor disposed in cavity 122 and to a plate line (e.g., in the sixth metal layer M6 (lines 116f). A via 114b is to be electrically coupled to a second electrode of the ferroelectric capacitor disposed in cavity 122 and to other interconnect structures (e.g., lines and vias) in interconnect layers 142, 141, and 140 and to a conductive contact (e.g., conductive contact 136) to provide a path to a transistor (e.g., transistor 135) in the device layer 134.

In a second example, a bottom side 127 of cavity 124 is aligned with the lower plane 115 (e.g., defined by lower edges of lines 116a) of the first metal layer M1 in the second interconnect layer 141, and extends to a top edge 125 of cavity 124 aligned with the upper plane 113 (e.g., defined by the upper edges of lines 116b) of the second metal layer M2 in the third interconnect layer 142. Thus, cavity 124 traverses interconnect layer 141 and the second metal layer M2 (lines 116b) in the third interconnect layer 142. A via 114b in the third interconnect layer 142 is to be electrically coupled to a first electrode of a ferroelectric capacitor disposed in cavity 124 and to a plate line (e.g., in the third metal layer M3 (lines 116c). A via 112 is to be electrically coupled to a second electrode of the ferroelectric capacitor disposed in cavity 124 and to a conductive contact (e.g., conductive contact 136) to provide a path to a transistor (e.g., transistor 135) in the device layer 134.

In a third example, a bottom side 127 of cavity 126 is aligned with the lower plane 115 (e.g., defined by the lower edges of lines 116e) of the fifth metal layer M5 in the sixth interconnect layer 145, and extends to a top edge 125 aligned with the upper plane 113 (e.g., defined by the upper edges of lines 116e) of the fifth metal layer M5 in the sixth interconnect layer 145. Thus, cavity 126 traverses only the fifth metal layer M5 (lines 116e) in the sixth interconnect layer 145. A via 114e in the sixth interconnect layer 145 is to be electrically coupled to a first electrode of a ferroelectric capacitor disposed in cavity 126 and to a plate line (e.g., in the sixth metal layer M6). A via 114d is to be electrically coupled to a second electrode of the ferroelectric capacitor disposed in cavity 126 and to other interconnect structures (e.g., lines and vias) in interconnect layers 144, 143, 142, 141, and 140 and to a conductive contact (e.g., conductive contact 136) to provide a path to a transistor (e.g., transistor 135) in the device layer 134.

In this example, the height or thickness of the fifth metal layer M5 (lines 116e) is substantially equivalent to the depth of cavity 126 (as measured along the Z-axis direction). Thus, the fifth metal layer M5 (lines 116e) would need to have a sufficient thickness such that a depth of cavity 126 is sufficient to accommodate the (vertical) length of the ferroelectric capacitor and a width of the cavity 126 is sufficient to accommodate the (horizontal) width of the ferroelectric capacitor.

In a fourth example, a bottom side 127 of cavity 128 is aligned with the lower plane 115 (e.g., defined by the lower edges of lines 116a) of the first metal layer M1 in the second interconnect layer 141, and extends to a top edge 125 aligned with the upper plane 113 (e.g., defined by the upper edges of lines 116d) of the fourth metal layer M4 in the fifth interconnect layer 144. Thus, cavity 128 traverses the interconnect layers 141, 142, 143 and the fourth metal layer M4 (lines 116d) in the fifth interconnect layer 144. A via 114d in the fifth interconnect layer 144 is to be electrically coupled to a first electrode of a ferroelectric capacitor disposed in cavity 128 and to a plate line (e.g., in the fifth metal layer M5). A via 112 is to be electrically coupled to a second electrode of the ferroelectric capacitor disposed in cavity 128 and to a conductive contact (e.g., conductive contact 136) to provide a path to a transistor (e.g., transistor 135) in the device layer 134.

The various examples of cavities 122, 124, 126, and 128 for holding ferroelectric capacitors illustrated in the cross-sectional view of processing layers 100 of a wafer or die are intended to be illustrative and nonlimiting. A cavity for holding a ferroelectric capacitor may traverse any number of interconnect layers (e.g., one, two, three, four, five, or more) based on the particular design of the integrated circuit on the die and the particular dimensions of the ferroelectric capacitor to be used.

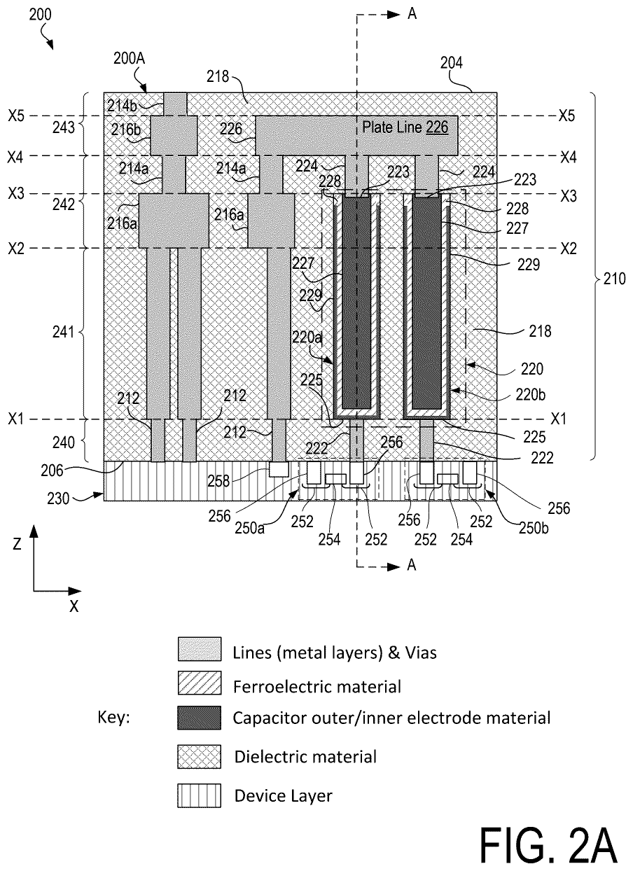

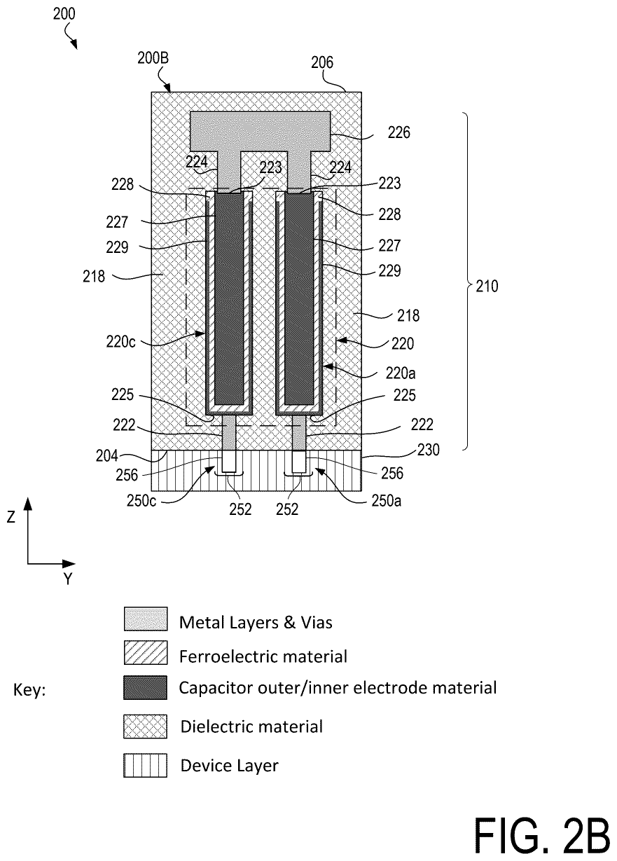

Turning to FIGS. 2A and 2B, which may be viewed together, simplified cross-sectional views of an integrated circuit structure 200 with an embedded FeRAM array are shown. The integrated circuit structure 200 may be included in an integrated circuit component. The FeRAM array may include a plurality of ferroelectric capacitors 220a-220c and a plurality of corresponding transistors 250a-250c.

FIG. 2A is a simplified cross-sectional view 200A of a first side of a back end of life (BEOL) structure 210 and device layer 230 of the integrated circuit structure 200 showing two example embedded ferroelectric capacitors 220a and 220b and two corresponding example access transistors 250a and 250b of the FeRAM array. FIG. 2B is a simplified cross-sectional view 200B of a second side of the BEOL stack structure 210 and device layer 230 of the integrated circuit structure 200, taken along A-A of FIG. 2A, showing two example ferroelectric capacitors 220a and 220c and two corresponding example access transistors 250a and 250c of the FeRAM array.

In FIGS. 2A and 2B, a key is provided indicating materials of various interconnect structures and layers shown in the cross-sectional views 200A and 200B. The cross-sectional view 200A shows the BEOL stack structure 210 and a device layer 230. The device layer 230 is below the BEOL stack structure 210, and may include any type of logic circuitry, including computational circuitry, logic gates, etc. Devices in the device layer may include transistors (e.g., transistors 135 of FIG. 1), resistors, capacitors, and any other semiconductor device used in the logic circuitry. Two example access transistors 250a and 250b and logic transistor 258, which are part of the FeRAM array are shown in the device layer 230. The integrated circuit component may also include a substrate (e.g., substrate 132 of FIG. 1), which has been omitted in FIGS. 2A and 2B for simplicity.

The BEOL stack structure 210 may include a metallization stack or inter-layer dielectric stack (ILD) in the form of a plurality of interconnect layers 240, 241, 242, and 243. Interconnect layer 241 represents one or more optional interconnect layers. The interconnect layers 240, 241, 242, and 243 comprise insulating material or dielectric material 218 and/or oxides, interspersed with conductive interconnect structures such as vias 212, 222, 214a, 214b, 224, and lines (or traces) 216a, 216b, and 226, where the lines define various metal layers (e.g., M(A), M(B)) and the vias define through dielectric vias (TDVs). The dielectric material 218 may be similar to the dielectric material 118 of FIG. 1. The conductive interconnect structures and contacts generally comprise a metal, such as copper (Cu). In some embodiments, the conductive interconnect structures and contacts may include one or more of gold, tungsten, aluminum, titanium, tantalum, molybdenum, magnesium, and cobalt (W, Mo, Ti, Au, Mg, Ta, Co, Al). The lines 216a and 216b of the metal layers M(A) and M(B), respectfully, may have the same thickness (or height) or different thicknesses (or heights).

The integrated circuit structure 200 comprises embedded memory. In one or more embodiments, the embedded memory in the integrated circuit component comprises an array of memory cells. In one example, the array of memory cells is a non-volatile FeRAM array. Generally, a single FeRAM cell includes an access transistor connected in series with a ferroelectric capacitor (also referred to as a 1T1C FeRAM cell). The ferroelectric capacitor includes two conductive portions (e.g., electrodes) and a dielectric portion that includes ferroelectric material between the two conductive portions. The ferroelectric capacitor is connected to a plate line with one of the conductive portions. The access transistor includes a gate between a source and a drain, where the gate is connected to a wordline of the FeRAM array, the source is connected to a bitline of the FeRAM array, and the drain is connected to the other conductive portion of the ferroelectric capacitor. Each capacitor in the FeRAM array can store one bit at a time.

In the integrated circuit component of FIGS. 2A and 2B, the FeRAM array includes a plurality of ferroelectric capacitors embedded in the BEOL stack structure 210 and a plurality of corresponding access transistors in the device layer. In the view 200A, two ferroelectric capacitors 220a and 220b and two corresponding access transistors 250a and 250b are visible. In the view 200B, two ferroelectric capacitors 220a and 220c and two corresponding access transistors 250a and 250c are visible. Although three capacitors 220a-220c and corresponding access transistors 250a-250c are shown in this example, other examples may include fewer or more capacitors and fewer or more access transistors. In some examples, neighboring cells may share a source or drain region of an access transistor.

As shown in FIGS. 2A-2B, each ferroelectric capacitor 220a-220c includes an outer conductive portion 229 (also referred to herein as electrode or terminal), an inner conductive portion 227 (also referred to herein as electrode or terminal), and a ferroelectric portion 228 (also referred to herein as a ferroelectric layer or dielectric layer) disposed between the inner conductive portion 227 and the outer conductive portion 229. Each access transistor 250a-250c includes a gate 254, source and drain (S/D) regions 252, and conductive contacts 256 for the S/D regions 252. Each of the outer conductive portions 229 of the capacitors 220 is electrically coupled with a conductive contact 256 of an S/D region 252 of the access transistor 250a, 250b, or 250c in the device layer 230. Each of the inner conductive portions 227 is connected by way of a plate line via 224 to a plate line 226. The plate line 226 may be configured in any suitable way so that voltage can be applied to the array of ferroelectric capacitors to toggle between reading and writing data. In one example, the plate line can be routed through one or more interconnect structures (e.g., vias, lines) to a conductive contact of another transistor. In this example, the plate line 226 is routed to the conductive contact of transistor 258 by via 214a, line 216a, and via 212 (and other vias and/or lines if one or more interconnect layers 241 are present).

The inner conductive portions 227 and outer conductive portions 229 of the ferroelectric capacitors 220 generally comprise conductive metals or metal oxides. Examples of metals that may be used to form the ferroelectric capacitors 220 may include, but are not necessarily limited to, platinum, iridium, gold, titanium, tungsten, iridium oxide, and ruthenium oxide. The ferroelectric layers of the ferroelectric capacitors 220 generally comprise a ferroelectric material that enables non-volatile polarization switching. Examples of ferroelectric materials that may be used in the ferroelectric layers may include, but are not necessarily limited to lead zirconate titanate (PZT), lead lanthanum zirconate titanate (PLZT), lead titanate, bismuth ferrite, strontium bismuth tantalate, strontium bismuth niobate, and hafnium-based ferroelectrics (e.g., hafnium zirconium oxide, doped hafnium oxide, etc.). Possible non-limiting material combinations for a ferroelectric capacitor 220 used for embodiments herein include tungsten, hafnium oxide, and tungsten, for the inner electrode (inner conductive portion 227), ferroelectric portion 228 (dielectric portion), and outer electrode (outer conductive portion 229), respectively. Another example includes platinum, PZT, and platinum for the inner electrode, ferroelectric layer, and outer electrode, respectively.

It should be noted that interconnect layer 241 is optional and may be omitted in some embodiments. In other examples, the optional interconnect layer 241 represents one or more interconnect layers, each of which may include interconnect structures in the form of lines (or traces) and vias. In one example, one or more higher metal layers are thinner than one or more lower metal layers in the stack.

In various aspects of the disclosure, the interconnect structures are to provide at least one electrically conductive path from a node in the device layer 230 through the interconnect layers 240-243 to a conductive contact on an upper surface of the BEOL stack structure 210 (e.g., similar to conductive contacts 148 on the BEOL stack structure 110 of FIG. 1), to the array of ferroelectric capacitors 220 (e.g., ferroelectric capacitors 220a, 220b, 220c, and others not shown) embedded in the interconnect layers, or to another node in the device layer 230. The interconnect structures (e.g., lines 216a, 216b, and 226 and vias 212, 222, 214a, 214b, and 224) of the interconnect layers 240-243 may be formed in any suitable pattern that forms the electrically conductive paths. Conductive contacts on the upper surface of the BEOL stack structure 210 may be electrically coupled to the integrated circuitry of a chiplet region or active region in another die, e.g., via a TSV or a TDV.

In FIGS. 2A and 2B, the vias 212, 222, 214a, 214b, 224 are each disposed in a single one of the interconnect layers 240, 242, and 243. It should be noted, however, that any one or more of the vias 212, 222, 214a, 214b, 224 may extend through (or traverse) multiple interconnect layers or be disposed in a single layer as shown. Furthermore, as indicated by optional interconnect layer 241, more interconnect layers may be provided in the BEOL stack structure 210 based on the particular needs and/or requirements of the integrated circuit component.

The configuration of the interconnect structures in the interconnect layers 240-243 will now be described. For simplicity, each of the vias 212, 222, 214a, 214b, 224 in FIG. 1 are shown and described below as being disposed in a single interconnect layer.

Interconnect layer 240 may include the lowest metal vias 212 and 222 (e.g., Via 0 or “V0”) of the BEOL stack structure 210 and may be formed directly on the device layer 230. In some embodiments, the first interconnect layer 240 may include V0 vias 212 to electrically couple conductive contacts (e.g., similar to conductive contacts 136 of S/D regions of transistors 135 in FIG. 1) in the device layer 230 to lines 216a in the second interconnect layer 242 (if the optional device layer 241 is omitted). In this case, lower ends of the vias 212 are electrically coupled to the conductive contacts in the device layer 230, respectively, and upper ends of the vias 212 are electrically coupled to the lines 216a, respectively, of the second interconnect layer 242. The first interconnect layer 240 also includes V0 vias 222, which may have lower ends electrically coupled with conductive contacts 256 and upper ends electrically coupled to outer conductive portion 229 of the ferroelectric capacitors 220, respectively.

Generally, the stack structure includes an upper edge 204 and a lower edge 206 on the device layer. FIGS. 2A-2B are examples, however, and numerous other interconnect layers could be provided within the upper edge 204 and the lower edge 206. It should be noted that, in some scenarios, the transistors 250a-250c, 258 (and/or other access transistors, transistors, or devices in the device layer) may partially extend into the dielectric material of the lowest interconnect layer (e.g., first interconnect layer 140) in which the lowest metal vias 112 are located. Furthermore, in some scenarios, the transistors 250a-250c, 258 (and/or other devices in the device layer) may partially extend into a substrate on which the device layer is formed (e.g., source and drain regions located in the substrate).

The second interconnect layer 242 may be formed directly on the first interconnect layer 240, or on the next lower interconnect layer if one or more interconnect layers represented by interconnect layer 241 are present. In some embodiments, the second interconnect layer 242 may include vias 214a to electrically couple lines 216a of the second interconnect layer 242 to lines 216b of the third interconnect layer 243. In this case, lower ends of vias 214a are electrically coupled to lines 216a in the second interconnect layer 242, and upper ends of vias 214a are electrically coupled to lines 216b or 226 in the third interconnect layer 143. The second interconnect layer 242 also includes plate line vias 224 to electrically couple plate line 226 to the ferroelectric capacitors 220. In this case, lower ends of the plate line vias 224 are electrically coupled to the inner conductive portion 227 of the ferroelectric capacitors 220, and upper ends of the plate line vias 224 are electrically coupled to the plate line 226. The portion of the second interconnect layer 242 that includes lines 216a, formed between dashed lines X2-X2 and X3-X3, may also be referred to as Metal A or “M(A)” layer. The vias 214a and 224 in the second interconnect layer 242 may also be referred to as Via A or “V(A).”

The third interconnect layer 243 may be formed directly on the second interconnect layer 242. In some embodiments, the third interconnect layer 243 may include vias 214b to electrically couple lines 216b of the third interconnect layer 243 to lines of the next higher interconnect layer, or to lines in one or more higher interconnect layers, or to conductive contacts of the BEOL stack structure 210 (e.g., similar to conductive contacts 148 of the BEOL stack structure 110 of FIG. 1). The portion of the third interconnect layer 243 that includes lines 216b and plate line 226, formed between dashed lines X4-X4 and X5-X5, may also be referred to as Metal B or “M(B)” layer. The vias 214b and plate line vias 224 may also be referred to as Via B or V(B).

FIGS. 2A and 2B illustrate an example implementation for embedded ferroelectric capacitors of an FeRAM array. The implementation shown in FIGS. 2A and 2B show embedded ferroelectric capacitors 220 arranged in a two-dimensional array formation. It should be noted, however, that an alternative implementation includes embedded ferroelectric capacitors arranged in a one-dimensional array formation. Furthermore, one or more one-dimensional arrays or two-dimensional arrays of ferroelectric capacitors could be embedded in an integrated circuit component.

Ferroelectric capacitors of an FeRAM array may be embedded in a BEOL stack structure in discrete or separate cavities that are formed in dielectric material 218 of any one or more interconnect layers. As shown in FIGS. 2A and 2B, in some embodiments the cavities may be formed in the BEOL stack structure 210 such that the ferroelectric capacitors 220 disposed therein are arranged in a substantially perpendicular orientation relative to the interconnect layers 240-243. In one or more embodiments, lower ends 225 of the ferroelectric capacitors 220 are aligned with the lower plane of a metal layer within an interconnect layer (e.g., represented by dashed line X1-X1), and upper ends 223 of the ferroelectric capacitors 220 are aligned with a top edge of a metal layer within an interconnect layer (e.g., represented by dashed line X3-X3). In other scenarios, a cavity in which a ferroelectric capacitor is disposed may extend above a top edge of a metal layer and/or below a bottom edge of the same (or different) metal layer.

Generally, cavities that hold ferroelectric capacitors in the BEOL stack structure 210 are formed in the size and shape of the ferroelectric capacitors that are disposed therein. As previously discussed herein, the cavities may be formed in any one or more interconnect layers of the BEOL stack structure, which may depend on the dimensions of the ferroelectric capacitors. In the example of FIGS. 2A and 2B, ferroelectric capacitors 220 are embedded in interconnect layer(s) 241, if present (between planes represented by dashed lines X1-X1 and X2-X2), and a metal layer M(A) of interconnect layer 242. In some scenarios, the ferroelectric capacitors may be embedded in a single metal layer of an interconnect layer (e.g., M(A), M(B), or a metal layer of interconnect layer(s) 241). In at least some examples, the ferroelectric capacitors vertically extend across one or more interconnect layers such that the ferroelectric capacitors are arranged substantially perpendicular each of the one or more interconnect layers.

In some scenarios the ferroelectric capacitors may be arranged in the cavities in an upside-down orientation. In this scenario, the plate line would be located in an interconnect layer below the inner electrodes of the ferroelectric capacitors, and multiple interconnect structures would form electrical conductive paths from the outer electrodes of the ferroelectric capacitors to the corresponding transistors in the device layer. Thus, regardless of the orientation of the ferroelectric capacitors, a metal layer of an interconnect layer may be positioned opposite to the exposed inner electrodes of the ferroelectric capacitors in order to provide a plate line for connection to the array.

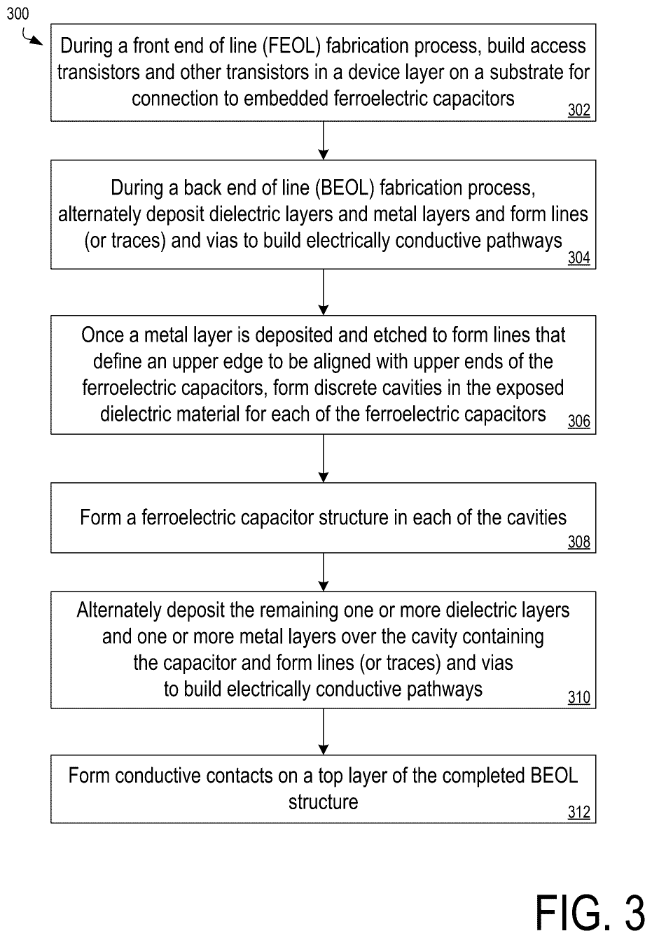

FIG. 3 is an example method 300 of a manufacturing flow for an integrated circuit component with ferroelectric capacitors embedded in the back end of line. At 302, during a front end of line (FEOL) fabrication process, access transistors are built in a device layer on a substrate for connection to ferroelectric capacitors that are to be formed in the BEOL fabrication process in the inter-layer dielectric stack (or metallization stack). In addition, another transistor is built in the device layer for connection to one or more interconnect structures that are to be formed in the BEOL fabrication process in the ILD stack. The interconnect structures are to form a path to a plate line for the ferroelectric capacitors.

At 304, during a back end of line (BEOL) fabrication process, dielectric layers and metal layers are alternately deposited and formed (e.g., using photolithography and/or etching) into connected lines and vias, lines and/or vias for connection to ferroelectric capacitors.

At 306, once a metal layer having an upper edge to be aligned with upper ends of the ferroelectric capacitors is deposited, and that metal layer is etched to form lines, the exposed dielectric material is etched to form discrete cavities for each of the ferroelectric capacitors.

At 308, the ferroelectric capacitors are formed in each of the cavities. The formation of a ferroelectric capacitor can include forming an outer metal layer, which substantially conforms to the shape of the inner surface (e.g., walls and floor) of the cavity, apply a ferroelectric layer on the inner surface of the outer metal layer, and fill the inner space defined by the ferroelectric layer with a second metal. In some embodiments, the second metal may be the same conductive metal as the first metal layer.

At 310, the remaining one or more dielectric layers and one or more metal layers are alternately deposited over the currently exposed interconnect layer and etched to form lines (or traces and vias to build electrically conductive paths. In one of the remaining metal layers, a plate line is formed for connection to plate line vias and interconnect structures forming an electrically conductive path to a transistor in the device layer for toggling voltage sent to the ferroelectric capacitors.

At 312, conductive contacts are formed on a top layer of the BEOL stack structure.

The multi-layer magnetoelectric, ferroelectric, and/or ferromagnetic structures described herein can be used in any processor unit or integrated circuit component described or referenced herein. An integrated circuit component comprising multi-layer magnetoelectric, ferroelectric, or ferromagnetic structures can be attached to a printed circuit board. In some embodiments, one or more additional integrated circuit components or other components, such as a battery or antenna, can be attached to the printed circuit board. In some embodiments, the printed circuit board and the integrated circuit component can be located in a computing device that comprises a housing that encloses the printed circuit board and the integrated circuit component is an integrated circuit structure comprising devices that include magnetoelectric, ferroelectric, or ferromagnetic structures can comprise other types of devices, such as electronic transistors (transistors such as CMOS transistors that operate through control of the flow of electric current and that do not rely upon the switching of the magnetization of a layer or component for operation).

It is to be understood that drawings illustrate idealized and/or simplified versions of structure cross-sections. In actual cross-sections, the lines, layers, and other elements illustrated in the drawings can have shapes that vary from those illustrated. For example, surfaces illustrated as planar possess undulations, bumps, or dishing features; sidewalls can have a taper to them; ninety-degree corners can be rounded; and lines, layers, and features can overlap more or less than illustrated.

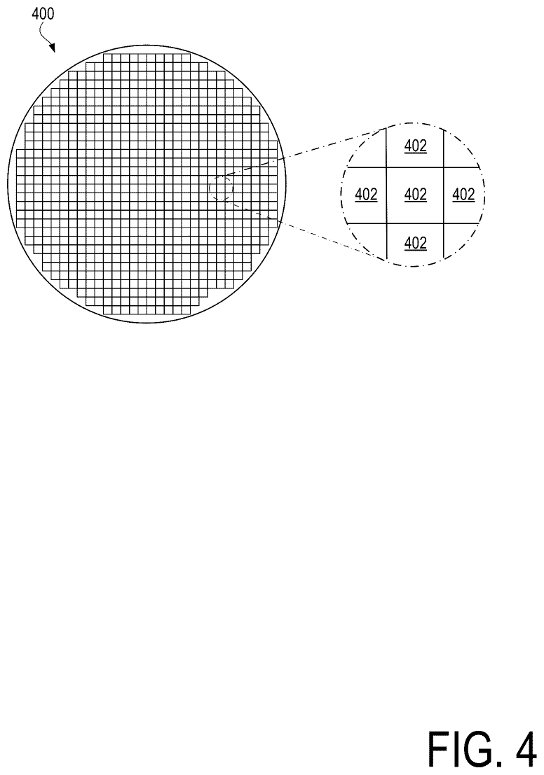

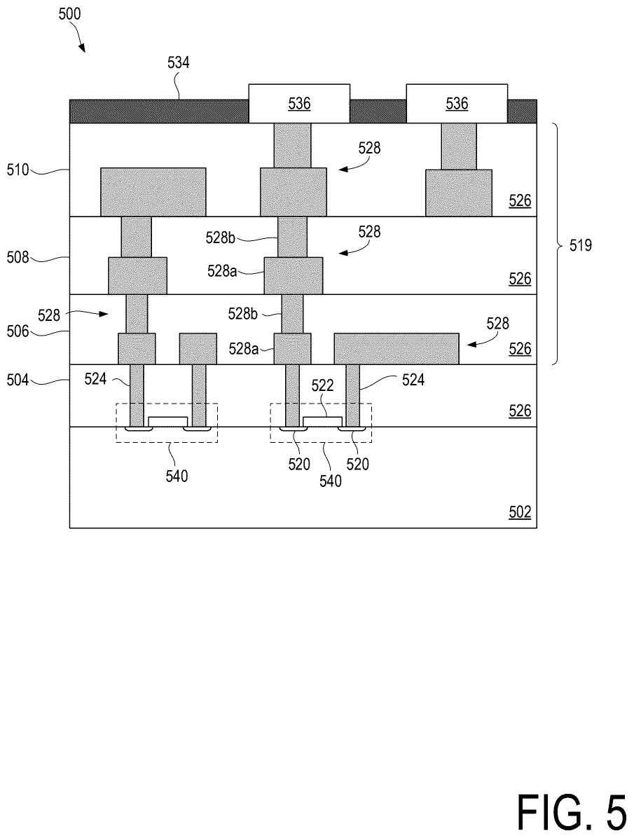

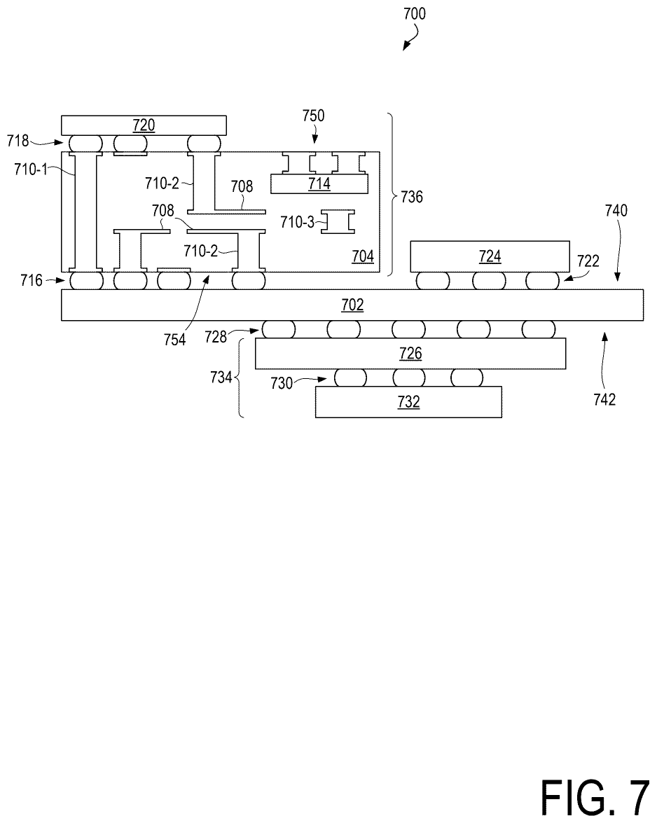

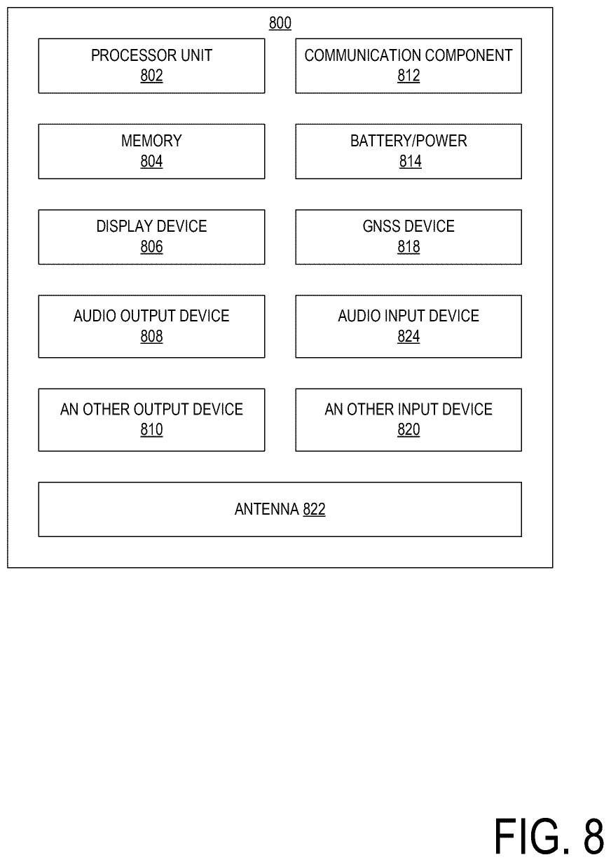

FIG. 4 is a top view of a wafer 400 and dies 402 that may be included in any of the embodiments disclosed herein (e.g., as any suitable ones of the integrated circuit structures 200 or 500 of FIGS. 2A-2B or FIG. 5, or included in integrated circuit device assembly 700 of FIG. 7, or included in electrical device 800 of FIG. 8). The wafer 400 may be composed of semiconductor material and dies 402 having integrated circuit structures formed on a surface of the wafer 400. The individual dies 402 may be a repeating unit of an integrated circuit product that includes any suitable integrated circuit. After the fabrication of the semiconductor product is complete, the wafer 400 may undergo a singulation process in which the dies 402 are separated from one another to provide discrete “chips” of the integrated circuit product. The dies 402 may include any of the integrated circuit components (e.g., FIGS. 1 and 2A-2B) references herein. The individual dies 402, comprising an integrated circuit component, may include one or more transistors (e.g., transistors 540 of FIG. 5 discussed below, transistors 135 of FIG. 1, transistors 250a-250c of FIGS. 2A-2B), supporting circuitry to route electrical signals to the transistors, passive components (e.g., signal traces, resistors, capacitors, or inductors), and/or any other integrated circuit components that can be fabricated on the wafer. In some embodiments, the wafer 400 or the dies 402 may include a memory device (e.g., a random access memory (RAM) device, such as a static RAM (SRAM) device, a ferroelectric RAM (FeRAM) device, a magnetic RAM (MRAM) device, a resistive RAM (RRAM) device, a conductive-bridging RAM (CBRAM) device, etc.), logic gates (e.g., AND, OR, NAND, and NOR gates), or any other suitable circuit element. Multiple ones of these devices and components may be combined on a single die. For example, a memory array formed by multiple memory devices may be formed on the same die as a processor unit (e.g., processor unit 802) or other logic configured to store information in the memory devices or execute instructions stored in the memory array. In some embodiments, a microelectronic assembly may be manufactured using a die-to-wafer assembly technique in which some dies 402 are attached to a wafer 400 that include other die, and the wafer 400 is subsequently singulated.

FIG. 5 is a cross-sectional view of an integrated circuit structure 500 that may be included in any of the embodiments disclosed herein (e.g., in any of the integrated circuit structures 200 or 500 of FIGS. 2A-2B or FIG. 5, or in integrated circuit device assembly 700 of FIG. 7, or in electrical device 800 of FIG. 8). Multiple instances of the integrated circuit structure 500 may be included in the dies 402 (FIG. 4). The integrated circuit structure 500 may be formed on a die substrate 502 (e.g., the wafer 400 of FIG. 4) and may be included in a die (e.g., the die 402 of FIG. 4). The integrated circuit structure 500 may be included in any of the integrated circuit components partially shown in and described with reference to, FIGS. 1 and 2A-2B in which an FeRAM array is implemented.

The die substrate 502 may be a semiconductor substrate composed of semiconductor material including, for example, n-type or p-type materials (or a combination of both). The die substrate 502 may include, for example, a crystalline substrate formed using a bulk silicon or a silicon-on-insulator (SOI) substructure. In some embodiments, the die substrate 502 can comprise a layer of silicon on top of an SOI layer with bulk silicon below the SOI layer. In some embodiments, the die substrate 502 may be formed using alternative materials, which may or may not be combined with silicon, that include, but are not limited to, germanium, indium antimonide, lead telluride, indium arsenide, indium phosphide, gallium arsenide, or gallium antimonide. Further materials classified as group II-VI, III-V, or IV may also be used to form the die substrate 502. Although a few examples of materials from which the die substrate 502 may be formed are described here, any material that may serve as a foundation for an integrated circuit structure 500 may be used. The die substrate 502 may be part of a singulated die (e.g., dies 402 of FIG. 4) or a wafer (e.g., wafer 400 of FIG. 4).

The integrated circuit structure 500 may include a device layer 504 disposed on the die substrate 502. The device layer 504 may include features of transistors 540 (e.g., metal oxide semiconductor field-effect transistors (MOSFETs)) formed on the die substrate 502. The transistors 540 may include, for example, source and drain regions (S/D regions 520), a gate 522 to control current flow between the S/D regions 520, and S/D contacts 524 to route electrical signals to and from the S/D regions 520. The transistors 540 may include additional features not depicted for the sake of clarity, such as device isolation regions, gate contacts, and the like. The transistors 540 may be similar to transistors 135 of FIG. 1 and/or the access transistors 250a-250c of FIGS. 2A-2B.

The transistors 540 are not limited to the type and configuration depicted in FIG. 5 and may include a wide variety of other types and configurations such as, for example, non-planar transistors, or a combination of planar and non-planar transistors. Non-planar transistors may include FinFET transistors, such as double-gate transistors or tri-gate transistors, and wrap-around or all-around gate transistors, such as nanoribbon, nanosheet, or nanowire transistors.

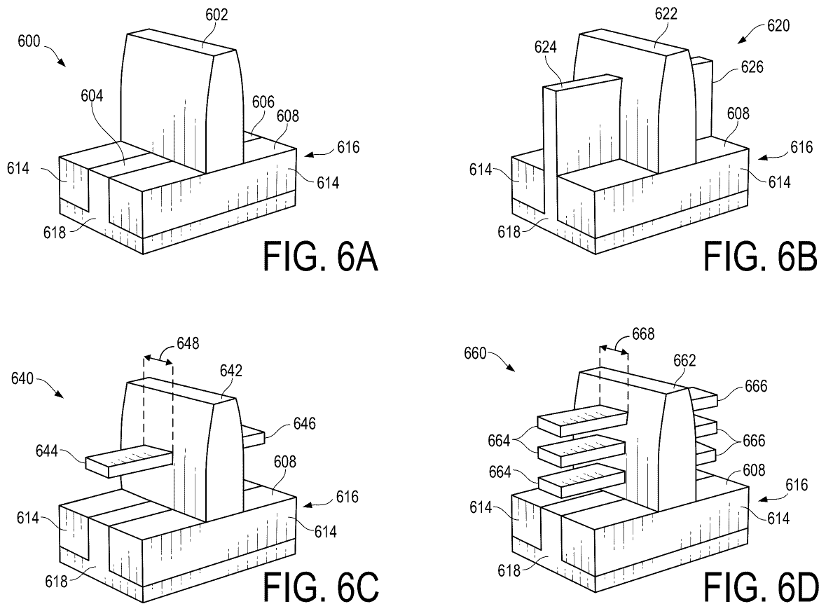

FIGS. 6A-6D are perspective views of example planar, FinFET, gate-all-around, and stacked gate-all-around transistors. The transistors illustrated in FIGS. 6A-6D are formed on a substrate 616 having a substrate surface 608 and a bulk region 618. Isolation regions 614 separate the source and drain regions of the transistors from other transistors.

FIG. 6A is a perspective view of an example transistor 600 comprising a gate 602 that controls current flow between a source region 604 and a drain region 606. The transistor 600 is planar in that the source region 604, the drain region 606 and the substrate surface 608 lie in the same plane.

FIG. 6B is a perspective view of an example transistor 620 comprising a gate 622 that controls current flow between a source region 624 and a drain region 626. The transistor 620 is non-planar in that the source region 624 and the drain region 626 comprise “fins” that extend upwards from the substrate surface 608. The transistor 620 can be referred to as a FinFET. As the gate 622 encompasses three sides of the fin that extends from the source region 624 to the drain region 626, the transistor 620 can be considered a tri-gate transistor. FIG. 6B illustrates one S/D fin extending through the gate 622, but multiple S/D fins can extend through the gate of a FinFET transistor.

FIG. 6C is a perspective view of a transistor 640 comprising a gate 642 that controls current flow between a source region 644 and a drain region 646. The transistor 640 is non-planar in that the source region 644 and the drain region 646 lie in a different plane than the substrate surface 608. As the gate 642 encompasses all sides of the channel region of the transistor 640 that extends from the source region 644 to the drain region 646, the transistor 640 can be referred to as a gate-all-around (GAA) transistor.

FIG. 6D is a perspective view of a transistor 660 comprising a gate 662 that controls current flow between multiple elevated source regions 664 and multiple elevated drain regions 666. The transistor 660 is a stacked GAA transistor as the gate controls the flow of current between multiple elevated S/D regions stacked on top of each other. The transistors 640 and 660 are considered gate-all-around transistors as the gates encompass all sides of the channel regions of the transistor that extends from the source regions to the drain regions. The transistors 640 and 660 can alternatively be referred to as nanowire, nanosheet, or nanoribbon transistors depending on the width (e.g., widths 648 and 668 of transistors 640 and 660, respectively) of the channel regions extending through the gate.

Returning to FIG. 5, transistors 540 may include a gate 522 formed of at least two layers, a gate dielectric, and a gate electrode. The gate dielectric may include one or more layers. The one or more layers may include silicon oxide, silicon dioxide, silicon carbide, and/or a high-k dielectric material.

The high-k dielectric material may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some embodiments, an annealing process may be carried out on the gate dielectric to improve its quality when a high-k material is used.

The gate electrode may be formed on the gate dielectric and may include at least one p-type work function metal or n-type work function metal, depending on whether the transistor is to be a p-type metal oxide semiconductor (PMOS) or an n-type metal oxide semiconductor (NMOS) transistor. In some implementations, the gate electrode may consist of a stack of two or more metal layers, where one or more metal layers are work function metal layers and at least one metal layer is a fill metal layer. Further metal layers may be included for other purposes, such as a barrier layer.

For PMOS transistors, metals that may be used for the gate electrode include, but are not limited to, ruthenium, palladium, platinum, cobalt, nickel, conductive metal oxides (e.g., ruthenium oxide), and any of the metals discussed below with reference to an NMOS transistor (e.g., for work function tuning). For NMOS transistors, metals that may be used for the gate electrode include, but are not limited to, hafnium, zirconium, titanium, tantalum, aluminum, alloys of these metals, carbides of these metals (e.g., hafnium carbide, zirconium carbide, titanium carbide, tantalum carbide, and aluminum carbide), and any of the metals discussed above with reference to a PMOS transistor (e.g., for work function tuning).

In some embodiments, such as in the FinFET illustrated in FIG. 6B, the gate electrode may have an upside-down U-shape that includes a top portion substantially parallel to the surface of the die substrate 502 and two side portions that are substantially perpendicular to the top surface of the die substrate 502. In other embodiments, such as the planar FET illustrated in FIG. 6A, at least one of the metal layers that form the gate electrode may be a planar layer that is substantially parallel to the top surface of the die substrate 502 without side portions. In other embodiments, the gate electrode may consist of a combination of U-shaped structures and planar, non-U-shaped structures. For example, the gate electrode may consist of one or more U-shaped metal layers formed atop one or more planar, non-U-shaped layers.

In some embodiments, a pair of sidewall spacers may be formed on opposing sides of the gate stack (comprising the gate dielectric and the gate electrode) to bracket the gate stack. The sidewall spacers may be formed from materials such as silicon nitride, silicon oxide, silicon carbide, silicon nitride doped with carbon, and silicon oxynitride. Processes for forming sidewall spacers are well known in the art and generally include deposition and etching process steps. In some embodiments, a plurality of sidewall spacer pairs may be used; for instance, two pairs, three pairs, or four pairs of sidewall spacers may be formed on opposing sides of the gate stack.

The S/D regions 520 may be formed within the die substrate 502 adjacent to the gate 522 of transistors 540. The S/D regions 520 may be formed using an implantation/diffusion process or an etching/deposition process, for example. In the former process, dopants such as boron, aluminum, antimony, phosphorous, or arsenic may be ion-implanted into the die substrate 502 to form the S/D regions 520. An annealing process that activates the dopants and causes them to diffuse further into the die substrate 502 may follow the ion implantation process. In the latter process, the die substrate 502 may first be etched to form recesses at the locations of the S/D regions 520. An epitaxial deposition process may then be carried out to fill the recesses with material that is used to fabricate the S/D regions 520. In some implementations, the S/D regions 520 may be fabricated using a silicon alloy such as silicon germanium or silicon carbide. In some embodiments, the epitaxially deposited silicon alloy may be doped in situ with dopants such as boron, arsenic, or phosphorous. In some embodiments, the S/D regions 520 may be formed using one or more alternate semiconductor materials such as germanium or a group III-V material or alloy. In further embodiments, one or more layers of metal and/or metal alloys may be used to form the S/D regions 520.

Electrical signals, such as power and/or information-carrying signals (e.g., input/output (I/O) signals, may be routed to and/or from devices (e.g., transistors 540) of the device layer 504 through one or more interconnect layers disposed on the device layer 504 (illustrated in FIG. 5 as interconnect layers 506-510). For example, electrically conductive features of the device layer 504 (e.g., the gate 522 and the S/D contacts 524) may be electrically coupled with interconnect structures 528 of the interconnect layers 506-510. The one or more interconnect layers 506-510 may form a metallization stack 519 (which can also be referred to as an “ILD stack” (inter-layer dielectric stack)) of the integrated circuit structure 500.

The interconnect structures 528 may be arranged within the interconnect layers 506-510 to route electrical signals according to a wide variety of designs; in particular, the arrangement is not limited to the particular configuration of interconnect structures 528 depicted in FIG. 5. In one example, an array of ferroelectric capacitors that form part of an FeRAM array may be embedded in the dielectric material of the interconnect layers 506-510, as previously discussed herein. Although a particular number of interconnect layers 506-510 is depicted in FIG. 5, embodiments of the present disclosure include integrated circuit structures having more or fewer interconnect layers than depicted.

In some embodiments, the interconnect structures 528 may include traces or lines 528a and/or vias 528b filled with an electrically conductive material such as a metal. The lines 528a may be arranged to route electrical signals in a direction of a plane that is substantially parallel with a surface of the die substrate 502 upon which the device layer 504 is formed. For example, the lines 528a may route electrical signals in a direction in and out of the page and/or in a direction across the page from the perspective of FIG. 5. The vias 528b may be arranged to route electrical signals in a direction of a plane that is substantially perpendicular to the surface of the die substrate 502 upon which the device layer 504 is formed. In some embodiments, lines 528a of different interconnect layers 506-510 are electrically coupled by vias 528b.

The interconnect layers 506-510 may include a dielectric material 526 within which the interconnect structures 528 are disposed, as shown in FIG. 5. In some embodiments, dielectric material 526 in different ones of the interconnect layers 506-510 may have different compositions; in other embodiments, the composition of the dielectric material 526 between different interconnect layers 506-510 may be the same. The device layer 504 may include a dielectric material 526 within which the transistors 540 are disposed and upon which a bottom layer of the metallization stack is located. The dielectric material 526 that is part of the device layer 504 may have a different composition than the dielectric material 526 included in the interconnect layers 506-510; in other embodiments, the composition of the dielectric material 526 in the device layer 504 may be the same as a dielectric material 526 included in any one of the interconnect layers 506-510.

A first interconnect layer 506 (which can include a Metal 1 or “M1” layer comprising the lines or traces) may be formed directly on the device layer 504. In some embodiments, the first interconnect layer 506 may include lines 528a and/or vias 528b, as shown. The lines 528a of the first interconnect layer 506 may be coupled with contacts (e.g., the S/D contacts 524) of the device layer 504. In some examples, a lower interconnect layer (e.g., V0 of FIG. 1) including vias (e.g., vias 112 of FIG. 1, vias 212 and 222 of FIGS. 2A-2B) couples the first interconnect layer 506 to the S/D contacts 524. The vias 528b of the first interconnect layer 506 may be coupled with the lines 528a of a second interconnect layer 508.

The second interconnect layer 508 (which can be referred to as a Metal 2 or “M2” layer) may be formed directly on the first interconnect layer 506. In some embodiments, the second interconnect layer 508 may include vias 528b to couple the lines 528a of the second interconnect layer 508 with the lines 528a of a third interconnect layer 510. Although the lines 528a and the vias 528b are structurally delineated with a line within individual interconnect layers for the sake of clarity, the lines 528a and the vias 528b may be structurally and/or materially contiguous (e.g., simultaneously filled during a dual-damascene process) in some embodiments.

The third interconnect layer 510 (which can include a Metal 3 or “M3” layer comprising lines or traces) (and additional interconnect layers, as desired) may be formed in succession on the second interconnect layer 508 according to similar techniques and configurations described in connection with the second interconnect layer 508 or the first interconnect layer 506. In some embodiments, the interconnect layers that are “higher up” in the metallization stack 519 in the integrated circuit structure 500 (i.e., farther away from the device layer 504) may be thicker than the interconnect layers that are lower in the metallization stack 519, with lines 528a and vias 528b in the higher interconnect layers being thicker than those in the lower interconnect layers.

The integrated circuit structure 500 may include a solder resist material 534 (e.g., polyimide or similar material) and conductive contacts 536 formed on the stack of interconnect layers 506-510. In FIG. 5, the conductive contacts 536 are illustrated as taking the form of bond pads. The conductive contacts 536 may be electrically coupled with interconnect structures 528 of the top-most layer in the metallization stack 519 and configured to route electrical signals between the transistors 540 and components external to the integrated circuit structure 500. For example, solder bonds may be formed on the conductive contacts 536 to mechanically and/or electrically couple an integrated circuit component comprising the integrated circuit structure 500 with another component (e.g., a printed circuit board). The integrated circuit structure 500 may include additional or alternate structures to route electrical signals from the interconnect layers 506-510; for example, the conductive contacts 536 may include other analogous features (e.g., posts) that can route the electrical signals between the transistors 540 and external components. The conductive contacts 536 may serve as the conductive contacts 148 of FIG. 1, as appropriate.

In some embodiments in which the integrated circuit structure 500 is part of a double-sided die, the integrated circuit structure 500 may include a second metallization stack (not shown) located on the opposite side of the die substrate 502 from the device layer 504. This second metallization stack may include multiple interconnect layers as discussed above with reference to the interconnect layers 506-510. Through-silicon vias (TSVs) that extend through the die substrate 502 can provide electrically conductive paths from the transistors 540 to the second metallization stack and the second metallization stack can electrically couple the TSVs to additional conductive contacts (not shown) located on the opposite side of the integrated circuit structure 500 from the conductive contacts 536.

In some embodiments, TSVs extending through the die substrate 502 can be used for routing power and ground signals from conductive contacts located on the opposite side of the integrated circuit structure 500 from the conductive contacts 536 to the transistors 540 and any other components integrated into the integrated circuit structure 500, and the metallization stack 519 can be used to route information-carrying signals from the conductive contacts 536 to transistors 540 and any other components integrated into the integrated circuit structure 500. Put another way, the routing of power and ground signals to the transistors 540 can be separated (via a back-side or bottom-side metallization stack and TSVs) from the routing of information-carrying signals to the transistors. The power and ground signals are provided by a backside or bottom-side metallization stack and TSVs, and information-carrying signals are provided by a topside metallization stack (e.g., metallization stack 519).

Several integrated circuit dies may be stacked with one or more TSVs in the individual stacked dies providing connection between one of the dies to any of the other dies in the stack. For example, one or more high-bandwidth memory (HBM) integrated circuit dies can be stacked on top of a base integrated circuit die and TSVs in the HBM dies can provide connection between the individual HBM dies and the base integrated circuit die. Conductive contacts can provide additional connections between adjacent integrated circuit dies in the stack. In some embodiments, the conductive contacts can be fine-pitch solder bumps (microbumps).

FIG. 7 is a cross-sectional view of an integrated circuit device assembly 700 that may include any of the integrated circuit structures (e.g., the integrated circuit structures 200 or 500 of FIGS. 2A-2B or FIG. 5) disclosed herein. The integrated circuit device assembly 700 includes a number of components disposed on a circuit board 702 (which may be a motherboard, system board, mainboard, etc.). The integrated circuit device assembly 700 includes components disposed on a first face 740 of the circuit board 702 and a second face 742 of the circuit board 702, the second face 742 opposing the first face 740. Generally, components may be disposed on either or both of the first face 740 and the second face 742 of the circuit board 702. Any of the integrated circuit components discussed below with reference to the integrated circuit device assembly 700 may take the form of any suitable ones of the embodiments of integrated circuit components that include integrated circuit structures (e.g., integrated circuit structures 200 or 500 of FIGS. 2A-2B or FIG. 5) or dies (e.g., dies 402 of FIG. 4) disclosed herein.

In some embodiments, the circuit board 702 may be a printed circuit board (PCB) including multiple metal (or interconnect) layers separated from one another by layers of dielectric material and interconnected by electrically conductive vias. The individual metal layers comprise conductive traces. The metal layers may be formed in a desired pattern to route electrical signals between the components electrically coupled to the circuit board 702. In other embodiments, the circuit board 702 may be a non-PCB substrate.

The integrated circuit device assembly 700 illustrated in FIG. 7 includes a package-on-interposer structure 736 coupled to the first face 740 of the circuit board 702 by coupling components 716. The coupling components 716 may electrically and mechanically couple the package-on-interposer structure 736 to the circuit board 702 and may include solder balls (as shown in FIG. 7), pins (e.g., as part of a pin grid array (PGA), contacts (e.g., as part of a land grid array (LGA)), male and female portions of a socket, an adhesive, an underfill material, and/or any other suitable electrical and/or mechanical coupling structure. (Thus, a coupling component may comprise a conductive contact.) The coupling components 716 may serve as the coupling components illustrated or described for any substrate assembly or substrate assembly components described herein (e.g., conductive contacts 148 of FIG. 1, conductive contacts similar to conductive contacts 148 and described with reference to integrated circuit structure 200 of FIGS. 2A-2B, conductive contacts 536 of FIG. 5), as appropriate.

The package-on-interposer structure 736 may include an integrated circuit component 720 coupled to an interposer 704. The interposer 704 may provide an intervening substrate used to bridge the circuit board 702 and the integrated circuit component 720. The integrated circuit component 720 is coupled to the interposer 704 by coupling components 718. The coupling components 718 may take any suitable form, such as the forms discussed above with reference to the coupling components 716. Although FIG. 7 shows just one integrated circuit component attached to the interposer, multiple integrated circuit components may be coupled to the interposer 704. Additional interposers may be coupled to the interposer 704.

The integrated circuit component 720 may be a packaged or unpacked integrated circuit product that includes one or more integrated circuit dies (e.g., the die 402 of FIG. 4, a die comprising the integrated circuit structure 200 of FIGS. 2A-2B, a die comprising the integrated circuit structure 500 of FIG. 5) and/or one or more other suitable components. A packaged integrated circuit component comprises one or more integrated circuit dies mounted on a package substrate with the integrated circuit dies and package substrate encapsulated in a casing material, such as a metal, plastic, glass, or ceramic. In one unpackaged example of an integrated circuit component 720, a single monolithic integrated circuit die comprises solder bumps attached to contacts on the die. The solder bumps allow the die to be directly attached to the interposer 704. The integrated circuit component 720 can comprise one or more computing system components, such as one or more processor units (e.g., system-on-a-chip (SoC), processor core, graphics processor unit (GPU), accelerator, chipset processor), I/O controller, memory, or network interface controller. In some embodiments, the integrated circuit component 720 can comprise one or more additional active or passive devices such as capacitors, decoupling capacitors, resistors, inductors, fuses, diodes, transformers, sensors, electrostatic discharge (ESD) devices, and memory devices.

In embodiments where the integrated circuit component 720 comprises multiple integrated circuit dies, the dies can be of the same type (a homogeneous multi-die integrated circuit component) or of two or more different types (a heterogeneous multi-die integrated circuit component). A multi-die integrated circuit component can be referred to as a multi-chip package (MCP) or multi-chip module (MCM).

In addition to comprising one or more processor units, the integrated circuit component 720 can comprise additional components, such as embedded DRAM, stacked high bandwidth memory (HBM), shared cache memories, input/output (I/O) controllers, or memory controllers. Any of these additional components can be located on the same integrated circuit die as a processor unit, or on one or more integrated circuit dies separate from the integrated circuit dies comprising the processor units. These separate integrated circuit dies can be referred to as “chiplets”. In embodiments where an integrated circuit component comprises multiple integrated circuit dies, interconnections between dies can be provided by the package substrate, one or more silicon interposers, one or more silicon bridges embedded in the package substrate (such as Intel® embedded multi-die interconnect bridges (EMIBs)), or combinations thereof.

Generally, the interposer 704 may spread connections to a wider or narrower pitch or reroute a connection to a different connection. For example, the interposer 704 may couple coupling components 718 having a first pitch to coupling components 716 having a wider pitch than the first pitch. In the embodiment illustrated in FIG. 7, the integrated circuit component 720 and the circuit board 702 are attached to opposing sides of the interposer 704. In other embodiments, the integrated circuit component 720 and the circuit board 702 may be attached to a same side of the interposer 704. In some embodiments, three or more components may be interconnected by way of the interposer 704.

In some embodiments, the interposer 704 may be formed as a PCB, including multiple metal layers separated from one another by layers of dielectric material and interconnected by electrically conductive vias. In some embodiments, the interposer 704 may be formed of an epoxy resin, a fiberglass-reinforced epoxy resin, an epoxy resin with inorganic fillers, a ceramic material, or a polymer material such as polyimide. In some embodiments, the interposer 704 may be formed of alternate rigid or flexible materials that may include the same materials described above for use in a semiconductor substrate, such as silicon, germanium, and other group III-V and group IV materials. The interposer 704 may include metal interconnects 708 and vias, including but not limited to through hole vias 710-1 (that extend from a first face 750 of the interposer 704 to a second face 754 of the interposer 704), blind vias 710-2 (that extend from the first face 750 or the second face 754 of the interposer 704 to an internal metal layer), and buried vias 710-3 (that connect internal metal layers).

In some embodiments, the interposer 704 can comprise a silicon interposer. Through silicon vias (TSV) extending through the silicon interposer can connect connections on a first face of a silicon interposer to an opposing second face of the silicon interposer. In some embodiments, an interposer 704 comprising a silicon interposer can further comprise one or more routing layers to route connections on a first face of the interposer 704 to an opposing second face of the interposer 704.

In some embodiments the interposer 704, as well as the circuit board 702, can comprise an amorphous solid layer of glass (which can be referred to a glass core or glass substrate). In some embodiments, the layer of glass can comprise silica (comprising silicon dioxide (SiO₂)), fused silica, aluminosilicate (comprising aluminum oxide (Al₂O₃) and silicon dioxide), borosilicate (comprising silicon dioxide and boron trioxide (B₂O₃)), or alumino-borosilicate (comprising aluminum oxide, silicon dioxide, and boron trioxide). In some embodiments, the layer of glass can comprise one or more of the following additives: aluminum oxide, boron trioxide, magnesium oxide (MgO), calcium oxide (CaO), strontium oxide (SrO), barium oxide (BaO), tin(IV) oxide (SnO₂), nitrous oxide (Na₂O), potassium oxide (K₂O), diphosphorous trioxide (P₂O₃), zirconium dioxide (ZrO₂), lithium oxide (Li₂O), titanium, and zinc. In some embodiments, the layer of glass can comprise silicon and oxygen, as well as one or more of aluminum, boron, magnesium, calcium, barium, tin, sodium, potassium, strontium, phosphorous, zirconium, lithium, titanium, and zinc. In some embodiments, the layer of glass comprises at least 23 percent silicon by weight, at least 26 percent oxygen by weight, and at least five percent aluminum by weight. In some embodiments, the layer of glass does not include an organic adhesive or an organic material. For example, the layer of glass is not a substrate or a board comprising glass fibers and an epoxy binder, such as a printed circuit board (PCB) comprising multiple metal (or interconnect) layers separated from one another by layers of dielectric material (e.g., FR-4 or other fiberglass-reinforced epoxy laminate) and interconnected by electrically conductive vias.

In some embodiments, the glass layer has a thickness in the range of about 50 microns to about 1.4 millimeters. In some embodiments, the glass layer is or is part of a multi-layer glass substrate (a coreless substrate). Individual glass layers in a multi-layer glass substrate can have a thickness in the range of about 25 microns to about 50 microns. In some embodiments, a glass layer can have a length in the range of about 10 millimeters to about 250 millimeters on a side (e.g., can have an area in the range of about 10 mm×10 mm to about 250 mm×250 mm). In some embodiments, the glass layer comprises a rectangular prism volume with sections or portions (e.g., through-glass vias) removed and filled with other metals (e.g., metal).

In some embodiments, redistribution layers (RDL) can be located on either or both sides of the glass layer to provide electrically conductive paths from top and/or bottom surfaces of the interposer 704 or circuit board 702 to the glass layer. The glass layer can comprise through-glass vias (TGVs) that extend through the glass layer to provide electrically conductive paths through the glass core, glass substrate, or glass layer.

The interposer 704 may further include embedded devices 714, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency devices, power amplifiers, power management devices, antennas, arrays, sensors, and microelectromechanical systems (MEMS) devices may also be formed on the interposer 704. The package-on-interposer structure 736 may take the form of any of the package-on-interposer structures known in the art.

The integrated circuit device assembly 700 may include an integrated circuit component 724 coupled to the first face 740 of the circuit board 702 by coupling components 722. The coupling components 722 may take the form of any of the embodiments discussed above with reference to the coupling components 716, and the integrated circuit component 724 may take the form of any of the embodiments discussed above with reference to the integrated circuit component 720.

The integrated circuit device assembly 700 illustrated in FIG. 7 further includes a package-on-package structure 734 coupled to the second face 742 of the circuit board 702 by coupling components 728. The package-on-package structure 734 may include an integrated circuit component 726 and an integrated circuit component 732 coupled together by coupling components 730 such that the integrated circuit component 726 is disposed between the circuit board 702 and the integrated circuit component 732. The coupling components 728 and 730 may take the form of any of the embodiments of the coupling components 716 discussed above, and the integrated circuit components 726 and 732 may take the form of any of the embodiments of the integrated circuit component 720 discussed above. The package-on-package structure 734 may be configured in accordance with any of the package-on-package structures known in the art.

FIG. 8 is a block diagram of an example electrical device 800 that may include any of the microelectronic assemblies disclosed herein. For example, any suitable ones of the components of the electrical device 800 may include one or more of the integrated circuit device assembly 700, integrated circuit component 720, or integrated circuit structures 200 or 500, integrated circuit dies 402 disclosed herein. A number of components are illustrated in FIG. 8 as included in the electrical device 800, but any one or more of these components may be omitted or duplicated, as suitable for the application. In some embodiments, some or all of the components included in the electrical device 800 may be attached to one or more motherboards mainboards, or system boards. In some embodiments, one or more of these components are fabricated onto a single system-on-a-chip (SoC) die.

Additionally, in various embodiments, the electrical device 800 may not include one or more of the components illustrated in FIG. 8, but the electrical device 800 may include interface circuitry for coupling to the one or more components. For example, the electrical device 800 may not include a display device 806, but may include display device interface circuitry (e.g., a connector and driver circuitry) to which a display device 806 may be coupled. In another set of examples, the electrical device 800 may not include an audio input device 824 or an audio output device 808, but may include audio input or output device interface circuitry (e.g., connectors and supporting circuitry) to which an audio input device 824 or audio output device 808 may be coupled.

The electrical device 800 may include one or more processor units 802. As used herein, the terms “processor unit,” “processing unit,” or “processor” may refer to any device or portion of a device that processes electronic data from registers and/or memory to transform that electronic data into other electronic data that may be stored in registers and/or memory. The one or more processor units 802 may include one or more digital signal processors (DSPs), application-specific integrated circuits (ASICs), central processing units (CPUs), graphics processing units (GPUs), general-purpose GPUs (GPGPUs), accelerated processing units (APUs), field-programmable gate arrays (FPGAs), neural network processing units (NPUs), data processor units (DPUs), accelerators (e.g., graphics accelerator, compression accelerator, artificial intelligence accelerator), controller cryptoprocessors (specialized processors that execute cryptographic algorithms within hardware), server processors, controllers, or any other suitable type of processor units. As such, the processor unit can be referred to as an XPU (or xPU).

The electrical device 800 may include a memory 804, which may itself include one or more memory devices such as volatile memory (e.g., dynamic random access memory (DRAM), static random-access memory (SRAM)), non-volatile memory (e.g., read-only memory (ROM), flash memory, chalcogenide-based phase-change non-voltage memories), solid state memory, and/or a hard drive. In some embodiments, the memory 804 may include memory that is located on the same integrated circuit die as the one or more processor units 802. This memory may be used as cache memory (e.g., Level 1 (L1), Level 2 (L2), Level 3 (L3), Level 4 (L4), Last Level Cache (LLC)) and may include embedded dynamic random-access memory (eDRAM) or spin transfer torque magnetic random-access memory (STT-MRAM).

In some embodiments of the electrical device 800, a first one of the one or more processor units 802 can be heterogeneous or asymmetric to a second one of the one or more processor units 802 in the electrical device 800. There can be a variety of differences between the one or more processor units 802 in a system in terms of a spectrum of metrics of merit including architectural, microarchitectural, thermal, power consumption characteristics, and the like. These differences can effectively manifest themselves as asymmetry and heterogeneity among the one or more processor units 802 in the electrical device 800.

In some embodiments, the electrical device 800 may include a communication component 812. For example, the communication component 812 can manage wireless communications for the transfer of data to and from the electrical device 800. The term “wireless” and its derivatives may be used to describe circuits, devices, systems, methods, techniques, communications channels, etc., that may communicate data through the use of modulated electromagnetic radiation through a nonsolid medium. The term “wireless” does not imply that the associated devices do not contain any wires, although in some embodiments they might not.

The communication component 812 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra mobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication component 812 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication component 812 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication component 812 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication component 812 may operate in accordance with other wireless protocols in other embodiments. The electrical device 800 may include an antenna 822 to facilitate wireless communications and/or to receive other wireless communications (such as AM or FM radio transmissions).

In some embodiments, the communication component 812 may manage wired communications, such as electrical, optical, or any other suitable communication protocols (e.g., IEEE 802.3 Ethernet standards). In some embodiments, the electrical device 800 comprises multiple communication components. For instance, a first communication component may be dedicated to shorter-range wireless communications such as Wi-Fi or Bluetooth, and a second communication component may be dedicated to longer-range wireless communications such as global positioning system (GPS), EDGE, GPRS, CDMA, WiMAX, LTE, EV-DO, or others. In some embodiments, a first communication component may be dedicated to wireless communications, and a second communication component may be dedicated to wired communications.

The electrical device 800 may include battery/power circuitry 814. The battery/power circuitry 814 may include one or more energy storage devices (e.g., batteries or capacitors) and/or circuitry for coupling components of the electrical device 800 to an energy source separate from the electrical device 800 (e.g., AC line power).

The electrical device 800 may include a display device 806 (or corresponding interface circuitry, as discussed above). The display device 806 may include one or more embedded or wired or wirelessly connected external visual indicators, such as a heads-up display, a computer monitor, a projector, a touchscreen display, a liquid crystal display (LCD), a light-emitting diode display, or a flat panel display.

The electrical device 800 may include an audio output device 808 (or corresponding interface circuitry, as discussed above). The audio output device 808 may include any embedded or wired or wirelessly connected external device that generates an audible indicator, such as speakers, headsets, or earbuds.

The electrical device 800 may include an audio input device 824 (or corresponding interface circuitry, as discussed above). The audio input device 824 may include any embedded or wired or wirelessly connected device that generates a signal representative of a sound, such as microphones, microphone arrays, or digital instruments (e.g., instruments having a musical instrument digital interface (MIDI) output). The electrical device 800 may include a Global Navigation Satellite System device (GNSS) (or corresponding interface circuitry, as discussed above), such as a Global Positioning System (GPS) device. The GNSS device 818 may be in communication with a satellite-based system and may determine a geolocation of the electrical device 800 based on information received from one or more GNSS satellites, as known in the art.

The electrical device 800 may include another output device 810 (or corresponding interface circuitry, as discussed above). Examples of the other output device 810 may include an audio codec, a video codec, a printer, a wired or wireless transmitter for providing information to other devices, or an additional storage device.

The electrical device 800 may include another input device 820 (or corresponding interface circuitry, as discussed above). Examples of the other input device 820 may include an accelerometer, a gyroscope, a compass, an image capture device (e.g., monoscopic or stereoscopic camera), a trackball, a trackpad, a touchpad, a keyboard, a cursor control device such as a mouse, a stylus, a touchscreen, proximity sensor, microphone, a bar code reader, a Quick Response (QR) code reader, electrocardiogram (ECG) sensor, PPG (photoplethysmogram) sensor, galvanic skin response sensor, any other sensor, or a radio frequency identification (RFID) reader.

The electrical device 800 may have any form factor, such as a hand-held or mobile electrical device (e.g., a cell phone, a smartphone, a mobile internet device, a music player, a tablet computer, a laptop computer, a 2-in-1 convertible computer, a portable all-in-one computer, a netbook computer, an ultrabook computer, a personal digital assistant (PDA), an ultra-mobile personal computer, a portable gaming console), a desktop electrical device, a server, a rack-level computing solution (e.g., blade, tray, or sled computing system), a workstation or other networked computing component, a printer, a scanner, a monitor, a set-top box, an entertainment control unit, a stationary gaming console, smart television, a vehicle control unit, a digital camera, a digital video recorder, a wearable electrical device or an embedded computing system (e.g., computing systems that are part of a vehicle, smart home appliance, consumer electronics product or equipment, manufacturing equipment). In some embodiments, the electrical device 800 may be any other electronic device that processes data. In some embodiments, the electrical device 800 may comprise multiple discrete physical components. Given the range of devices that the electrical device 800 can be manifested as in various embodiments, in some embodiments, the electrical device 800 can be referred to as a computing device or a computing system.

In the above description, specific details are set forth, but embodiments of the technologies described herein may be practiced without these specific details. Well-known circuits, structures, and techniques have not been shown in detail to avoid obscuring an understanding of this description. Phrases such as “an embodiment,” “various embodiments,” “some embodiments,” and the like may include features, structures, or characteristics, but not every embodiment necessarily includes the particular features, structures, or characteristics.

Some embodiments may have some, all, or none of the features described for other embodiments. “First,” “second,” “third,” and the like describe a common object and indicate different instances of like objects being referred to. Such adjectives do not imply objects so described must be in a given sequence, either temporally or spatially, in ranking, or any other manner.

Various terminology that may be used herein is now described. “Connected” may indicate elements are in direct physical or electrical contact with each other and “coupled” may indicate elements cooperate or interact with each other, but they may or may not be in direct physical or electrical contact. Furthermore, the terms “comprising,” “including,” “having,” and the like, as used with respect to embodiments of the present disclosure, are synonymous. Terms modified by the word “substantially” include arrangements, orientations, spacings, or positions that vary slightly from the meaning of the unmodified term. For example, a stereoscopic camera with a field of view of substantially 180 degrees includes cameras that have a field of view within a few degrees of 180 degrees. For example, layers, faces, or features that are referred to as being substantially parallel can refer to layers, faces, or features that are within a few degrees of being parallel with each other, and layers, faces, or features that are referred to as being substantially perpendicular to each other can refer to features that are within +/−15 degrees of being perpendicular to each other.

As used herein, the phrase “located on” in the context of a first layer or component located on a second layer or component refers to the first layer or component being directly physically attached to the second part or component (no layers or components between the first and second layers or components) or physically attached to the second layer or component with one or more intervening layers or components. As used herein, the term “adjacent” refers to layers or components that are arranged next to each other (e.g., side-by-side, top and bottom, but may not necessarily be in contact with each other).

Certain terminology may also be used herein for the purpose of reference only, and thus are not intended to be limiting. For example, terms such as “upper,” “lower,” “above,” “below,” “bottom,” and “top” refer to directions in the Figures to which reference is made. Terms such as “front,” “back,” “rear,” and “side” describe the orientation and/or location of layers, components, portions of components, structures, lines, vias, substrates, etc., within a consistent but arbitrary frame of reference, which is made clear by reference to the text and the associated Figures describing the layers, component, portions of components, etc. under discussion. Such terminology may include the words specifically mentioned above, derivatives thereof, and words of similar import.

As used herein, the term “integrated circuit component” refers to a packaged or unpacked integrated circuit product. A packaged integrated circuit component comprises one or more integrated circuit dies mounted on a package substrate with the integrated circuit dies and package substrate encapsulated in a casing material, such as a metal, plastic, glass, or ceramic. In one example, a packaged integrated circuit component contains one or more processor units mounted on a substrate with an exterior surface of the substrate comprising a solder ball grid array (BGA). In one example of an unpackaged integrated circuit component, a single monolithic integrated circuit die comprises solder bumps attached to contacts on the die. The solder bumps allow the die to be directly attached to a printed circuit board. An integrated circuit component can comprise one or more of any computing system component described or referenced herein or any other computing system component, such as a processor unit (e.g., system-on-a-chip (SoC), processor core, graphics processor unit (GPU), accelerator, chipset processor), I/O controller, memory, or network interface controller.

As used herein, the term “electronic component” can refer to an active electronic component (e.g., processing unit, memory, storage device, transistor) or a passive electronic component (e.g., resistor, inductor, capacitor).

As used herein, the terms “operating”, “executing”, or “running” as they pertain to software or firmware in relation to a system, device, platform, or resource are used interchangeably and can refer to software or firmware stored in one or more computer-readable storage media accessible by the system, device, platform or resource, even though the software or firmware instructions are not actively being executed by the system, device, platform, or resource.

As used herein, the phrase “electrically conductively coupled,” which may be used interchangeably with “conductively coupled,” refers to the presence of one or more electrically conductive paths between components that are recited as being electrically conductively coupled. Electrically conductive paths (also referred to herein as “conductive paths”) correspond to electrically conductive traces and vias that are to conduct electrical signals when an integrated circuit device assembly 700 that includes an integrated circuit component having the integrated circuit structure 200 of FIGS. 2A-2B is in operation. The electrically conductive paths are thus to conduct electrical signals within active (electrically active) regions the integrated circuit structure 200. The electrically conductive paths include, for example, through-vias, traces, and further, any electrically conductive paths to and from any active or passive components or devices. For example, with reference to FIG. 2A, the ferroelectric capacitor 220a is electrically conductively coupled to the access transistor 250a and to the transistor 258 due to the presence of electrically conductive paths through the integrated circuit structure and conductive contacts 256 on the access transistor 250a and conductive contacts on the logic transistor 258.

As used in this application and the claims, a list of items joined by the term “and/or” can mean any combination of the listed items. For example, the phrase “A, B, and/or C” can mean A; B; C; A and B; A and C; B and C; or A, B and C. As used in this application and the claims, a list of items joined by the term “at least one of” can mean any combination of the listed terms. For example, the phrase “at least one of A, B, or C” can mean A; B; C; A and B; A and C; B and C; or A, B, and C. Moreover, as used in this application and the claims, a list of items joined by the term “one or more of” can mean any combination of the listed terms. For example, the phrase “one or more of A, B, and C” can mean A; B; C; A and B; A and C; B and C; or A, B, and C.

As used in this application and the claims, the phrase “individual of” or “respective of” following by a list of items recited or stated as having a trait, feature, etc. means that all of the items in the list possess the stated or recited trait, feature, etc. For example, the phrase “individual of A, B, or C, comprise a sidewall” or “respective of A, B, or C, comprise a sidewall” means that A comprises a sidewall, B comprises sidewall, and C comprises a sidewall.

The disclosed methods, apparatuses, and systems are not to be construed as limiting in any way. Instead, the present disclosure is directed toward all novel and nonobvious features and aspects of the various disclosed embodiments, alone and in various combinations and subcombinations with one another. The disclosed methods, apparatuses, and systems are not limited to any specific aspect or feature or combination thereof, nor do the disclosed embodiments require that any one or more specific advantages be present or problems be solved.

Theories of operation, scientific principles, or other theoretical descriptions presented herein in reference to the apparatuses or methods of this disclosure have been provided for the purposes of better understanding and are not intended to be limiting in scope. The apparatuses and methods in the appended claims are not limited to those apparatuses and methods that function in the manner described by such theories of operation.

Although the operations of some of the disclosed methods are described in a particular, sequential order for convenient presentation, it is to be understood that this manner of description encompasses rearrangement, unless a particular ordering is required by specific language set forth herein. For example, operations described sequentially may in some cases be rearranged or performed concurrently. Moreover, for the sake of simplicity, the attached figures may not show the various ways in which the disclosed methods can be used in conjunction with other methods.

The following examples pertain to additional embodiments of technologies disclosed herein.

The following examples pertain to embodiments in accordance with this specification. Example A1 provides an apparatus that includes: a plurality of interconnect layers including at least one dielectric material, a first interconnect layer comprising a first interconnect structure, and a second interconnect layer above the first interconnect layer; and a capacitor embedded in at least the second interconnect layer of the plurality of interconnect layers, and the capacitor includes an inner conductive portion, an outer conductive portion, and a dielectric portion comprising ferroelectric material, and the dielectric portion is located between the inner conductive portion and the outer conductive portion, and the first interconnect structure couples the outer conductive portion of the capacitor to a first transistor below the first interconnect layer.

Example A2 comprises the subject matter of Example A1, and the stack structure includes one or more layers between a lower end of the capacitor and the device layer.

Example A3 comprises the subject matter of any one of Examples A1-A2, and the stack structure includes one or more layers above an upper end of the capacitor.

Example A4 comprises the subject matter of any one of Examples A1-A3, and further including a first electrically conductive path including at least a second interconnect structure comprising an electrically conductive material, and the first electrically conductive path is conductively coupled to the second conductive portion of the capacitor and to a drain region of the first transistor or a source region of the first transistor.

Example A5 comprises the subject matter of Example A4, and the first electrically conductive path traverses one or more layers of the stack structure.

Example A6 comprises the subject matter of any one of Examples A1-A5, and the first conductive portion of the capacitor is coupled to the first interconnect structure of the first layer.

Example A7 comprises the subject matter of Example A6, and the first interconnect structure of the first layer is conductively coupled to one or more other capacitors in one or more other cavities, respectively, within the stack structure.

Example A8 comprises the subject matter of Example A7, and further including a second electrically conductive path including at least a third interconnect structure comprising electrically conductive material, and the second electrically conductive path is conductively coupled to the first interconnect structure in the first layer and to a second transistor of the device layer.

Example A9 comprises the subject matter of any one of Examples A1-A8, and the ferroelectric material includes one of hafnium zirconium oxide, hafnium oxide, lead zirconate titanate, lead lanthanum zirconate titanate, lead titanate, bismuth ferrite, strontium bismuth tantalate, or strontium bismuth niobate.

Example A10 provides a processor unit, and the processor unit includes the subject matter of any one of Examples A1-A9.

Example A11 provides a system that includes a display device and the subject matter of Example A10.

Example A12 provides an integrated circuit device assembly that includes a circuit board and the subject matter of Example A10.

Example A13 provides a computing device that includes a housing, and the housing encloses the integrated circuit device assembly of Example A12.

Example B1 provides an apparatus comprising: a stack structure including a plurality of layers, and a first layer of the plurality of layers includes a first interconnect structure and a first dielectric material; and a ferroelectric capacitor in a cavity within the stack structure, and the ferroelectric capacitor is conductively coupled to the first interconnect structure in the first layer and is further conductively coupled to a first transistor in a device layer, and one or more of the plurality of layers of the stack structure are disposed between the device layer and the ferroelectric capacitor.

Example B2 comprises the subject matter of Example B1, and the first interconnect structure is conductively coupled to one or more other ferroelectric capacitors in one or more other cavities, respectively, within the stack structure.

Example B3 comprises the subject matter of any one of Example B2, and the ferroelectric capacitor and the one or more other ferroelectric capacitors are arranged in a one-dimensional array formation or a two-dimensional array formation in the stack structure.

Example B4 comprises the subject matter of any one of Examples B2-B3, and the first interconnect structure is further conductively coupled to a second transistor of the device layer.

Example B5 comprises the subject matter of any one of Examples B1-B4, and the ferroelectric capacitor comprises an inner electrode coupled to the first interconnect structure in the first layer, an outer electrode coupled to the first transistor, and a ferroelectric layer between the inner electrode and the outer electrode, and the first layer is above the ferroelectric capacitor, and the first transistor is below the ferroelectric capacitor.

Example B6 comprises the subject matter any one of Examples B1-B5, and the ferroelectric capacitor comprises ferroelectric material, and the ferroelectric material includes one of hafnium zirconium oxide, hafnium oxide, lead zirconate titanate, lead lanthanum zirconate titanate, lead titanate, bismuth ferrite, strontium bismuth tantalate, or strontium bismuth niobate.

Example B7 provides a processor unit that comprises the subject matter of any one of Examples B1-B6.

Example B8 provides an integrated circuit device assembly that includes a circuit board and the subject matter of Example B7.

Example B9 provides a computing device that includes a housing, and the housing encloses the integrated circuit device assembly of Example B8.

Example C1 provides an apparatus including: a plurality of interconnect layers including at least one dielectric material, a first interconnect layer comprising a first interconnect structure, and a second interconnect layer above the first interconnect layer. The apparatus further includes a capacitor embedded in at least the second interconnect layer of the plurality of interconnect layers, and the capacitor includes an inner conductive portion, an outer conductive portion, and a dielectric portion comprising ferroelectric material and located between the inner conductive portion and the outer conductive portion, and the first interconnect structure couples the outer conductive portion of the capacitor to a first transistor below the first interconnect layer.

Example C2 comprises the subject matter of Example C1, and one or more interconnect layers of the plurality of interconnect layers are between the first transistor and the capacitor.

Example C3 comprises the subject matter of any one of Examples C1-C2, and one or more other interconnect layers of the plurality of interconnect layers are above the second interconnect layer.

Example C4 comprises the subject matter of any one of any one of Examples C1-C3, and a second interconnect structure of the second interconnect layer couples the inner conductive portion of the capacitor to a third interconnect structure in a third interconnect layer of the plurality of interconnect layers.

Example C5 comprises the subject matter of Example C4, and the third interconnect layer is above the second interconnect layer.

Example C6 comprises the subject matter of any one of Examples C1-C5, and the third interconnect layer is conductively coupled to two or more ferroelectric capacitors embedded in at least the second interconnect layer of the plurality of interconnect layers and to a second transistor of the device layer.

Example C7 comprises the subject matter of any one of Examples C1-C6, and the first interconnect structure is coupled to a drain region of the first transistor or to a source region of the first transistor.

Example C8 comprises the subject matter of any one of Examples C1-C7, and the ferroelectric material includes one of hafnium zirconium oxide, hafnium oxide, lead zirconate titanate, lead lanthanum zirconate titanate, lead titanate, bismuth ferrite, strontium bismuth tantalate, or strontium bismuth niobate.

Example C9 provides a processor unit, and the processor unit includes the subject matter of any one of Examples C1-C8.

Example C10 provides a system that includes a display device and the subject matter of Example C9.

Example C11 provides an integrated circuit device assembly that includes a circuit board and the subject matter of Example C9.

Example C12 provides a computing device that includes a housing, and the housing encloses the integrated circuit device assembly of Example C11.

1. An apparatus, comprising:
a device layer including a first transistor;
a stack structure above the device layer, the stack structure including:
a first layer including a first interconnect structure and a first dielectric material; and
a second layer between the device layer and the first layer; and
a capacitor in a cavity within the stack structure, wherein the capacitor includes a first conductive portion, a second conductive portion conductively coupled to the first transistor, and a dielectric portion comprising ferroelectric material, wherein the dielectric portion is located between the first conductive portion and the second conductive portion.

2. The apparatus of claim 1, wherein the stack structure includes one or more layers between a lower end of the capacitor and the device layer.

3. The apparatus of claim 1, wherein the stack structure includes one or more layers above an upper end of the capacitor.

4. The apparatus of claim 1, further comprising:
a first electrically conductive path including at least a second interconnect structure comprising an electrically conductive material, wherein the first electrically conductive path is conductively coupled to the second conductive portion of the capacitor and to a drain region of the first transistor.

5. The apparatus of claim 4, wherein the first electrically conductive path traverses one or more layers of the stack structure.

6. The apparatus of claim 1, wherein the first conductive portion of the capacitor is coupled to the first interconnect structure of the first layer.

7. The apparatus of claim 6, wherein the first interconnect structure of the first layer is conductively coupled to one or more other capacitors in one or more other cavities, respectively, within the stack structure.

8. The apparatus of claim 7, further comprising:
a second electrically conductive path including at least a third interconnect structure comprising electrically conductive material, wherein the second electrically conductive path is conductively coupled to the first interconnect structure in the first layer and to a second transistor of the device layer.

9. The apparatus of claim 1, wherein the ferroelectric material includes one of hafnium zirconium oxide, hafnium oxide, lead zirconate titanate, lead lanthanum zirconate titanate, lead titanate, bismuth ferrite, strontium bismuth tantalate, or strontium bismuth niobate.

10. An integrated circuit device assembly comprising a circuit board and a processor unit, wherein the processor unit includes the apparatus of claim 1.

11. A computing device comprising a housing, wherein the housing encloses the integrated circuit device assembly of claim 10.

12. An apparatus, comprising:
a stack structure including a plurality of layers, wherein a first layer of the plurality of layers includes a first interconnect structure and a first dielectric material; and
a ferroelectric capacitor in a cavity within the stack structure, wherein the ferroelectric capacitor is conductively coupled to the first interconnect structure in the first layer and is further conductively coupled to a first transistor in a device layer, wherein one or more of the plurality of layers of the stack structure are disposed between the device layer and the ferroelectric capacitor.

13. The apparatus of claim 12, wherein the first interconnect structure is conductively coupled to one or more other ferroelectric capacitors in one or more other cavities, respectively, within the stack structure.

14. The apparatus of claim 13, wherein the ferroelectric capacitor and the one or more other ferroelectric capacitors are arranged in a one-dimensional array formation or a two-dimensional array formation in the stack structure.

15. The apparatus of claim 13, wherein the first interconnect structure is further conductively coupled to a second transistor of the device layer.

16. The apparatus of claim 12, wherein the ferroelectric capacitor comprises:
an inner electrode coupled to the first interconnect structure in the first layer, wherein the first layer is above the ferroelectric capacitor;
an outer electrode coupled to the first transistor, wherein the first transistor is below the ferroelectric capacitor; and
a ferroelectric layer between the inner electrode and the outer electrode.

17. An apparatus, comprising:
a plurality of interconnect layers including at least one dielectric material, a first interconnect layer comprising a first interconnect structure, and a second interconnect layer above the first interconnect layer; and
a capacitor embedded in at least the second interconnect layer of the plurality of interconnect layers, wherein the capacitor includes an inner conductive portion, an outer conductive portion, and a dielectric portion comprising ferroelectric material and located between the inner conductive portion and the outer conductive portion, wherein the first interconnect structure couples the outer conductive portion of the capacitor to a first transistor below the first interconnect layer.

18. The apparatus of claim 17, wherein one or more interconnect layers of the plurality of interconnect layers are between the first transistor and the capacitor, and wherein one or more other interconnect layers of the plurality of interconnect layers are above the second interconnect layer.

19. The apparatus of claim 17, wherein a second interconnect structure of the second interconnect layer couples the inner conductive portion of the capacitor to a third interconnect structure in a third interconnect layer of the plurality of interconnect layers, wherein the third interconnect layer is above the second interconnect layer.

20. The apparatus of claim 17, wherein the third interconnect layer is conductively coupled to two or more ferroelectric capacitors embedded in at least the second interconnect layer of the plurality of interconnect layers and to a second transistor of the device layer.
